(19) United States
(12) Patent Application Publication
(10) Pub. No.: US 2025/0268043 A1
(43) Pub. Date: Aug. 21, 2025

(54) DISPLAY APPARATUS

(71) Applicant: LG Display Co., Ltd., Seoul (KR)

(72) Inventor: Su Yeong LEE, Paju-si (KR)

(73) Assignee: LG Display Co., Ltd., Seoul (KR)

(21) Appl. No.: 19/057,731

(22) Filed: Feb. 19, 2025

(30) Foreign Application Priority Data
Feb. 21, 2024 (KR) 10-2024-0025283

(51) Int. Cl. H10K 59/131; G09G 3/3233; H10K 59/121; H10K 59/126; H10K 59/40; H10K 59/80

(52) U.S. Cl. CPC H10K 59/131; G09G 3/3233; H10K 59/1213; H10K 59/126; H10K 59/40; H10K 59/873; G09G 2300/0426; G09G 2300/0819; G09G 2300/0842; G09G 2354/00

(57) ABSTRACT

A display apparatus can include a display panel having an active area and a non-active area. A plurality of gate lines, a plurality of data lines, and a plurality of unit pixels are disposed in the active area. The display apparatus can further include a data driving circuit connected to the plurality of data lines, and one or more data link lines disposed in the non-active area and configured to electrically connect the plurality of data lines to the data driving circuit. The one or more data link lines can include at least two layers.

### CROSS-REFERENCE TO RELATED APPLICATIONS

This application claims priority to Korean Patent Application No. 10-2024-0025283, filed in the Republic of Korea on Feb. 21, 2024, the entire contents of which is hereby expressly incorporated by reference into the present application.

### BACKGROUND

### Field

The present disclosure relates to a display apparatus.

### Discussion of the Related Art

Image display apparatuses, which render a variety of information on a screen, are core technologies of the information communication age, and are being developed toward further thinness, further lightness, greater portability, and higher performance. As such, display apparatuses, which can be manufactured to have a light and thin structure, are being highlighted.

As concrete examples of such a display apparatus, there are a liquid crystal display (LCD) apparatus, a quantum dot (QD) display apparatus, a field emission display (FED) apparatus, an organic light emitting diode (OLED) display apparatus, etc.

Among various display apparatuses, an organic display apparatus is a self-luminous display apparatus and, as such, does not require a separate light source, differently from a liquid crystal display apparatus. Accordingly, the organic display apparatus can be manufactured to have a light and thin structure. In addition, the organic display apparatus is not only advantageous in terms of power consumption according to low-voltage driving, but also has excellent color rendering, fast response time, wide viewing angle, and high contrast ratio (CR). In this regard, the organic display apparatus is being highlighted as a next-generation display apparatus and research thereon is being conducted.

Such a display apparatus can include a data driver, a gate driver, and pixels. The data driver can provide data signals to the pixels through data link lines and data lines formed in a non-active area of the display panel.

However, a parasitic capacitance can be formed between adjacent ones of the data link lines. In this case, different parasitic capacitances can be generated at different pixels and, as such, fine vertical line defects can be generated.

### SUMMARY OF THE DISCLOSURE

Accordingly, the present disclosure is directed to a display apparatus that substantially obviates one or more problems due to limitations and disadvantages of the related art.

It is an object of the present disclosure to provide a display apparatus capable of equalizing parasitic capacitances among data link lines.

It is another object of the present disclosure to provide a display apparatus capable of enhancing accuracy of data voltages output to pixels from data link lines associated with the same color through equalization of parasitic capacitances among the data link lines.

It is another object of the present disclosure to provide a display apparatus capable of enhancing brightness compensation consistency and display quality of pixels through enhancement in accuracy of data voltages output to pixels from data link lines associated with the same color.

Objects of the present disclosure are not limited to the above-described object, and other objects of the present disclosure not yet described will be more clearly understood by those skilled in the art from the following detailed description.

To achieve these objects and other advantages and in accordance with the purpose of the disclosure, as embodied and broadly described herein, a display apparatus includes a display panel including an active area and a non-active area, a plurality of gate lines, a plurality of data lines, and a plurality of unit pixels being disposed in the active area, a data driving circuit connected to the plurality of data lines, and one or more data link lines disposed in the non-active area and configured to electrically connect the plurality of data lines to the data driving circuit, the one or more data link lines including at least two layers.

Detailed matters of various embodiments of the present disclosure are included in the following detailed description and the accompanying drawings.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a block diagram of a display apparatus according to one or more embodiments of the present disclosure;

FIG. 2 is a circuit diagram of a pixel included in the display apparatus according to an embodiment of the present disclosure;

FIG. 3 is a cross-sectional view showing the display apparatus according to an embodiment of the present disclosure;

FIG. 4 is a diagram showing data link lines configured to interconnect a data driving integrated circuit (IC) and each of a plurality of sub-pixels of a display panel in a display apparatus according to an embodiment of the present disclosure;

FIG. 5 is a diagram showing data link lines configured to interconnect a data driving IC and each of a plurality of sub-pixels of a display panel in a display apparatus according to another embodiment of the present disclosure;

FIG. 6 is a sectional view showing disposition of data link lines in a display apparatus according to an embodiment of the present disclosure;

FIG. 7 is a sectional view showing disposition of data link lines in a display apparatus according to another embodiment of the present disclosure;

FIG. 8 is a sectional view showing disposition of data link lines in a display apparatus according to another embodiment of the present disclosure;

FIG. 9 is a sectional view showing disposition of data link lines in a display apparatus according to another embodiment of the present disclosure;

FIG. 10 is a sectional view showing disposition of data link lines in a display apparatus according to another embodiment of the present disclosure; and

FIG. 11 is a sectional view showing disposition of data link lines in a display apparatus according to another embodiment of the present disclosure.

### DETAILED DESCRIPTION OF THE EMBODIMENTS

Hereinafter, various embodiments of the present disclosure will be described in detail with reference to the accompanying drawings. Throughout the present disclosure, the same reference numerals designate the same constituent elements, respectively. Further, the term “can” fully encompasses all the meanings and coverages of the term “may.”

In the following description of the present disclosure, a detailed description of known technologies or configurations incorporated herein will be omitted when it can obscure the subject matter of the present disclosure. Furthermore, the following terms associated with constituent elements are selected taking into consideration ease of preparation of the disclosure, and can differ from the names of the corresponding elements in practice.

The shape, size, ratio, angle, number and the like shown in the drawings to illustrate the embodiments of the present disclosure are only for illustration and are not limited to the contents shown in the drawings. Wherever possible, the same reference numbers will be used throughout the drawings to refer to the same or like parts.

In the following description, detailed descriptions of technologies related to the present disclosure can be omitted so as not to unnecessarily obscure the subject matter of the present disclosure.

When terms such as “including”, “having” and “comprising” are used throughout the specification, an additional component can be present, unless “only” is used. A component described in a singular form encompasses components in a plural form unless particularly stated otherwise.

It should be interpreted that the components included in the embodiment of the present disclosure include an error range, although there is no additional particular description thereof.

In describing a variety of embodiments of the present disclosure, when terms for a positional relationship such as “on”, “above”, “under” and “next to” are used, at least one intervening element can be present between two elements unless “immediately” or “directly” is used.

In describing a variety of embodiments of the present disclosure, when a temporal relationship is described, for example, when terms for temporal relationship of events such as “after”, “subsequently”, “next”, and “before” are used, there can also be the case in which the events are not continuous, unless “immediately” or “directly” is used.

In the meantime, although terms including an ordinal number, such as first or second, can be used to describe a variety of constituent elements, the constituent elements are not limited to the terms, and the terms are used only for the purpose of discriminating one constituent element from other constituent elements. Accordingly, a first constituent element can represent a second constituent element within the scope of the present disclosure unless particularly stated otherwise.

The respective features of various embodiments according to the present disclosure can be partially or entirely joined or combined and technically variably related or operated, and the embodiments can be implemented independently or in combination.

Hereinafter, a display apparatus according to various embodiments of the present disclosure will be described with reference to the accompanying drawings. All the components of each display apparatus according to all embodiments of the present disclosure are operatively coupled and configured.

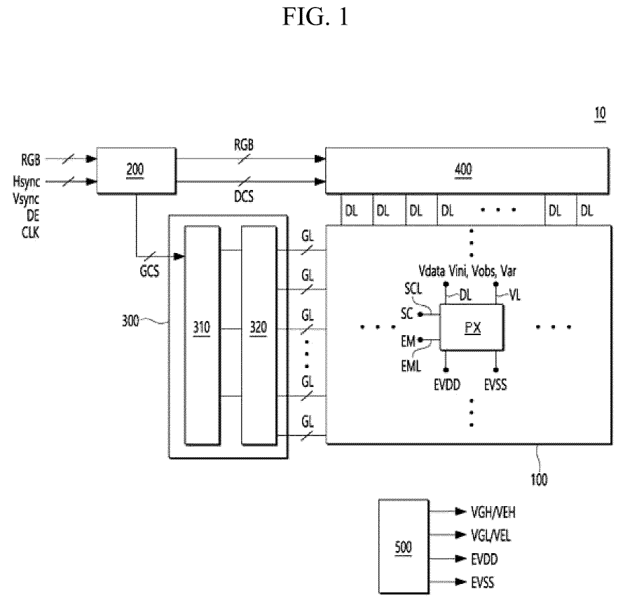

FIG. 1 is a block diagram of a display apparatus according to one or more embodiments of the present disclosure.

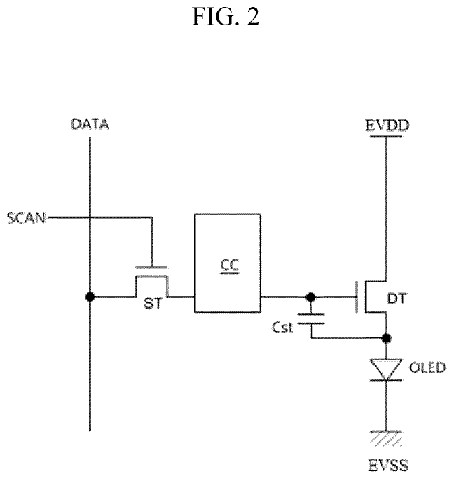

FIG. 2 is a circuit diagram of a pixel included in the display apparatus according to an embodiment of the present disclosure.

Referring to FIG. 1, the display apparatus according to one or more embodiments of the present disclosure includes a display panel 100, a data driving circuit 400, a gate driving circuit 300, a power generator 500, and a timing controller 200.

One or more pixels P can be disposed at the display panel 100. A plurality of pixels P can be disposed in regions in which a plurality of data lines DL and/or a plurality of gate lines GL intersect each other. Pixels P disposed on the same horizontal line can constitute one pixel row. The pixels P disposed in one pixel row can be connected to one gate line GL, and the one gate line GL can include at least one scan line and at least one emission line. For example, each pixel P can be connected to one data line DL, at least one scan line, and at least one emission line. Of course, embodiments of the present disclosure are not limited to the above-described conditions.

The data driving circuit 400 can drive the data lines DL. The gate driving circuit 300 can drive the gate lines GL. The power generator 500 can supply electric power required for driving of each of the plurality of pixels P.

The plurality of pixels P can receive a high-level drive voltage EVDD, a low-level drive voltage EVSS, etc. from the power generator 500 in common. One or more pixels P can receive a bias voltage Vobs, a reset voltage VAR, and an initialization voltage Vini from a power line VL.

Thin film transistors (TFTs) constituting one pixel P can each be implemented by an oxide TFT including an oxide semiconductor layer, but embodiments of the present disclosure are not limited thereto. The oxide TFT can be advantageous in terms of area enlargement of the display panel 100 when electron mobility, process deviations, etc. are taken into consideration. Of course, the present disclosure is not limited to the above-described conditions, and the semiconductor layer of the TFT can be constituted by amorphous silicon, low-temperature polysilicon, polysilicon, or the like.

Each pixel P can include a light emitting element, for example, an organic light emitting diode (OLED), a driving TFT configured to supply current to the light emitting element, a switching TFT configured to supply a data voltage to the driving TFT, and a storage capacitor configured to store the data voltage supplied to the driving TFT. Of course, embodiments of the present disclosure are not limited to the above-described conditions. The storage capacitor can maintain the data voltage for one frame.

Each pixel P can further include a plurality of TFTs and another storage capacitor in order to compensate for a variation in threshold voltage of the driving TFT.

Referring to FIG. 2, each pixel P can include a switching transistor ST, a driving transistor DT, a compensation circuit CC, a light emitting element OLED, and a storage capacitor Cst.

The light emitting element OLED (e.g., organic light emitting diode) can operate to emit light in accordance with drive current formed by the driving transistor DT.

The switching transistor ST can perform a switching operation such that a data signal supplied through a data line DL, corresponding to a scan signal supplied through a gate line GL, is stored in the storage capacitor Cst as a data voltage.

The driving transistor DT can operate to enable a predetermined amount of drive current to flow between a high-level voltage line EVDD and a low-level voltage line EVSS, corresponding to the data voltage stored in the storage capacitor Cst.

The compensation circuit CC is a circuit configured to compensate a threshold voltage of the driving transistor DT, etc. The compensation circuit CC can include one or more thin film transistors and a capacitor. The compensation circuit CC can be variously configured in accordance with compensation methods.

For example, although the pixel P shown in FIG. 2 is configured to have a 2T (transistor) 1C (capacitor) structure including the switching transistor ST, the driving transistor DT, the storage capacitor Cst, and the light emitting element OLED, the pixel P can be configured to have various structures of 3T1C, 4T2C, 5T2C, 6T1C, 6T2C, 7T1C, 7T2C, 8T1C, etc. when the compensation circuit CC is added thereto. Of course, embodiments of the present disclosure are not limited to the above-described conditions.

A touch part or touch sensors can be disposed on the display panel 100. Touch input can be sensed using separate touch sensors or can be sensed through pixels P. The touch sensors can be disposed on a screen of the display panel 100 in an on-cell type or an add-on type or can be implemented as in-cell type touch sensors built in the display panel 100.

The timing controller 200 can control driving timings of the data driving circuit 400 and the gate driving circuit 300. The timing controller 200 can re-arrange digital video data RGB input thereto from an outside thereof, to be matched with the resolution of the display panel 100, and can then supply the re-arranged digital video data RGB to the data driving circuit 400.

In addition, the timing controller 200 can generate a data control signal DDC for control of an operation timing of the data driving circuit 400 and a gate control signal GDC for control of an operation timing of the gate driving circuit 300, based on timing signals such as a vertical synchronization signal Vsync, a horizontal synchronization signal Hsync, a dot clock signal CLK, a data enable signal DE, etc.

The timing controller 200 can multiply an input frame frequency by i times, thereby controlling operation timings of the display panel drivers at a frame frequency corresponding to an “input frame frequency×i” Hz (i being a positive integer greater than 0). The input frame frequency is 60 Hz in a national television standards committee (NTSC) system, and is 50 Hz in a phase-alternating line (PAL) system. Of course, embodiments of the present disclosure are not limited to the above-described conditions.

The data driving circuit 400 can convert the digital video data RGB input thereto from the timing controller 200 into an analog data voltage based on the data control signal DDC, and can then supply the analog data voltage to each data line DL.

The data driving circuit 400 can include at least one source drive IC (SIC). The source drive IC can convert digital video data of an input image into an analog gamma compensation voltage under control of the timing controller 200, thereby generating a data voltage, and can then output the data voltage to the data lines DL. The source drive IC can be mounted on a flexible circuit board, which can be bent, for example, on a chip-on-film (COF), or can be directly bonded to a substrate in a non-active area of the display panel 100 through a chip-on-glass (COG) process. Of course, embodiments of the present disclosure are not limited to the above-described conditions.

The COFs can be bonded to a pad area of the display panel 100 and a source PCB through an anisotropic conductive film (ACF). Input pins of the COFs can be electrically connected to output terminals (pads) of the source PCB. Output pins of the COFs can be electrically connected to data pads formed at the substrate of the display panel 100 through the ACF.

Although the data driving circuit 400 is shown in FIG. 1 as being singularly disposed at one side of the display panel 100, the data driving circuit 400 is not limited in terms of number and position. For example, the data driving circuit 400 can be constituted by one or more integrated circuits (ICs) such that the data driving circuit 400 is disposed at one side of the display panel 100 in a state of being divided into a plurality of ICs.

The gate driving circuit 300 can generate a scan signal and an emission control signal based on the gate control signal GDC. The gate driving circuit 300 can include at least one scan driver 310 and an emission driver 320.

The at least one scan driver 310 can generate a scan signal SC and can supply the scan signal to the gate lines GL in a row sequential manner, in order to drive at least one scan line SCL connected to each pixel row. The at least one scan driver 310 can output a scan pulse in response to a start pulse and a shift clock from the timing controller 200, and can then shift the scan pulse in accordance with a shift clock timing.

The emission driver 320 can generate an emission control signal EM and can then supply one or more emission lines EML connected to each pixel row in a row sequential manner in order to drive the emission lines EML. The emission driver 320 can output an emission control signal pulse in response to the start pulse and the shift clock from the timing controller 200, and can then sequentially shift the emission control signal pulse in accordance with the shift clock.

The scan signal SC can include a scan pulse swinging between a gate-on voltage VGL and a gate-off voltage VGH. The emission control signal EM can include an emission control signal pulse swinging between a gate-on voltage VEL and a gate-off voltage VEH. The scan pulse can select pixels P of a line on which a data voltage Vdata will be written. The emission control signal EM can define an emission time of the pixels P.

Each gate line GL can supply the scan signal SC and the emission control signal EM to one or more pixels P, and each data line DL can supply the data voltage Vdata to one or more pixels P. In accordance with various embodiments, each gate line GL can include one or more scan lines SCL for supply of the scan signal SC and one or more emission control signal lines EML for supply of the emission control signal EM.

The power generator 500, which is a power supplier, can generate DC power required for driving of a pixel array and the display panel drivers of the display panel 100, using a DC-DC converter. The DC-DC converter can include a charge pump, a regulator, a buck converter, a boost converter, etc. Of course, embodiments of the present disclosure are not limited to the above-described conditions.

The power supply 500 can receive a DC input voltage from a host system, thereby generating DC voltages such as a gate-on voltage VGL/VEL, a gate-off voltage VGH/VEH, a high-level drive voltage EVDD, a low-level drive voltage EVSS, etc.

The gate-on voltage VGL/VEL and the gate-off voltage VGH/VEH can be supplied to the level shifter and the gate driving circuit 300. The high-level drive voltage EVDD and the low-level drive voltage EVSS can be supplied to the pixels P in common.

The plurality of pixels P of the display panel 100 can include at least a first pixel, a second pixel, and a third pixel. The first pixel, the second pixel, and the third pixel can emit light of different colors, respectively. For example, the first pixel can be a red pixel, the second pixel can be a green pixel, and the third pixel can be a blue pixel.

The plurality of pixels P can have an equal size or different sizes, respectively. The first pixel, the second pixel, and the third pixel can be designed to have different sizes, taking into consideration lifespans, color balance, etc. of the light emitting elements OLED respectively included in the first pixel, the second pixel, and the third pixel. Of course, embodiments of the present disclosure are not limited to the above-described conditions.

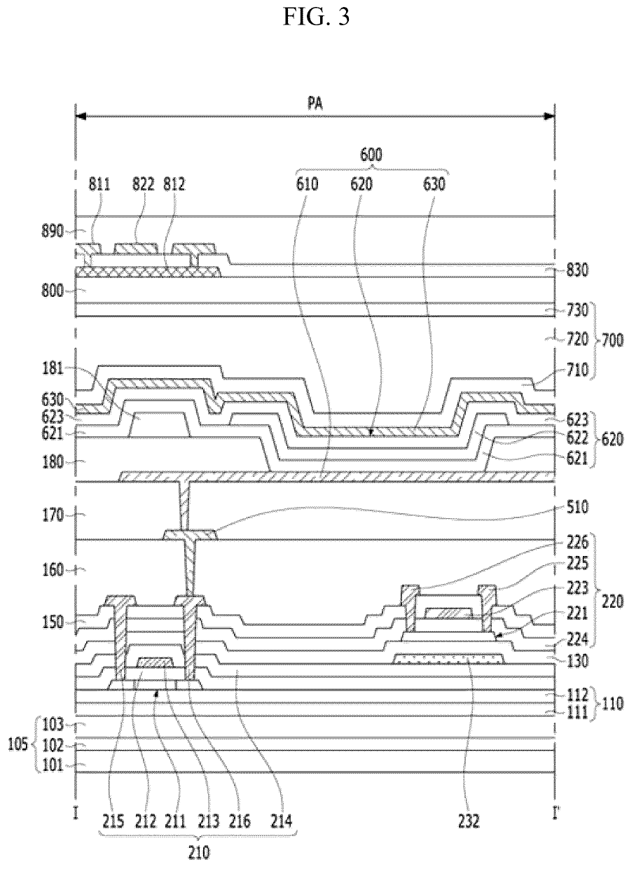

FIG. 3 is a cross-sectional view showing the display apparatus according to an embodiment of the present disclosure.

Referring to FIG. 3, the display apparatus according to the embodiment of the present disclosure can include a substrate 105. The substrate 105 can include an insulating material. For example, the substrate 105 can include glass or plastic. Of course, embodiments of the present disclosure are not limited to the above-described conditions. The substrate 105 can have a multilayer structure, but embodiments of the present disclosure are not limited thereto. For example, the substrate 105 can have a structure in which a first substrate layer 101, a substrate insulating layer 102, and a second substrate layer 103 are sequentially disposed or stacked. Of course, embodiments of the present disclosure are not limited to the above-described conditions.

The second substrate layer 103 can include the same material as that of the first substrate layer 101. Of course, embodiments of the present disclosure are not limited to the above-described conditions. For example, the first substrate layer 101 and the second substrate layer 103 can include a polymer material such as polyimide (PI). Of course, embodiments of the present disclosure are not limited to the above-described conditions. The substrate insulating layer 102 can include an insulating material. Accordingly, in the display apparatus according to the embodiment of the present disclosure, the substrate 105 can have flexibility. As a result, in the display apparatus according to the embodiment of the present disclosure, damage to the substrate 105 caused by bending stress can be prevented.

The substrate 105 can include an active area, a bending area, and a pad area. An image to be provided to the user can be rendered in the active area. For example, the active area can include a plurality of pixel areas PA. Each pixel area PA can render a particular color. For example, a light emitting element 600 can be disposed in each pixel area PA. The light emitting element 600 can emit light representing a particular color. For example, the light emitting element 600 can include a first electrode 610, an emission layer 620, and a second electrode 630 disposed on the substrate 105.

The first electrode 610 can include a conductive material. The first electrode 610 can be constituted by a material capable of having high reflectivity. For example, the first electrode 610 can include a metal such as aluminum (Al) or silver (Ag), but embodiments of the present disclosure are not limited thereto. The first electrode 610 can have a multilayer structure. For example, the first electrode 610 can have a structure in which a reflective electrode made of a metal is interposed between transparent electrodes made of a transparent conductive material such as indium tin oxide (ITO) or indium zinc oxide (IZO). Of course, embodiments of the present disclosure are not limited to the above-described conditions.

The emission layer 620 can generate light of a brightness corresponding to a voltage difference between the first electrode 610 and the second electrode 630. For example, the emission layer 620 can include an emission material layer (EML) 622 including an emission material. The emission material can include an organic material, an inorganic material, or a hybrid material. For example, the display apparatus according to the embodiment of the present disclosure can be an organic light emitting display apparatus in which an emission layer 620 includes an emission material layer 622 made of an organic material. Of course, embodiments of the present disclosure are not limited to the above-described conditions, and the emission layer 620 can include an inorganic emission material. For example, the emission layer 620 can be constituted by a material for manufacture of a quantum dot light emitting diode (QLED), a micro-LED, a mini-LED, or the like. Of course, embodiments of the present disclosure are not limited to the above-described conditions.

The emission layer 620 can have a multilayer structure. For example, the emission layer 620 can include at least one of a first common layer 621 disposed between the first electrode 610 and the emission material layer 622 or a second common layer 623 disposed between the emission material layer 622 and the second electrode 630. Each of the first common layer 621 and the second common layer 623 can include at least one of a hole injection layer (HIL), a hole transport layer (HTL), a hole blocking layer (HBL), an electron blocking layer (EBL), an electron transport layer (ETL), or an electron injection layer (EIL). Of course, embodiments of the present disclosure are not limited to the above-described conditions. For example, in the display apparatus according to the embodiment of the present disclosure, the first common layer 621 can include at least one of a hole injection layer (HIL), an electron blocking layer (EBL), or a hole transport layer (HTL), and the second common layer 623 can include at least one of an electron transport layer (ETL), a hole blocking layer (HBL), or an electron injection layer (EIL).

The second electrode 630 can include a conductive material. The second electrode 630 can include a material different from that of the first electrode 610, but embodiments of the present disclosure are not limited thereto. For example, the second electrode 630 can be a transparent electrode made of a transparent conductive material such as indium tin oxide (ITO) or indium zinc oxide (IZO). The second electrode 630 can have higher transmittance than that of the first electrode 610. In the display apparatus according to the embodiment of the present disclosure, accordingly, light generated by the emission layer 620 can be emitted through the second electrode 630.

A driving circuit can be disposed in each pixel area PA. The driving circuit can generate drive current to be provided to the light emitting element 600. The driving circuit can be electrically connected to signal lines GL, DL, EVDD, and EVSS. For example, each pixel area PA can be constituted by the signal lines GL, DL, EVDD, and EVSS. The signal lines GL, DL, EVDD, and EVSS can transmit various signals for rendering of an image. For example, the signal lines GL, DL, EVDD, and EVSS can include a gate line GL configured to apply a gate signal, a data line DL configured to apply a data signal, and drive voltage supply lines EVDD and EVSS configured to supply drive voltages, but embodiments of the present disclosure are not limited thereto. The driving circuit can generate drive current corresponding to a data signal in accordance with a gate signal. Operation of the light emitting element 600 can be maintained for one frame. For example, the driving circuit can include a first thin film transistor 210 and a second thin film transistor 220, but embodiments of the present disclosure are not limited thereto.

The first thin film transistor 210 can be electrically connected to the light emitting element 600. The first thin film transistor 210 can supply, to the light emitting element 600, drive current corresponding to a data signal. For example, the first thin film transistor 210 can be disposed between the light emitting element 600 and one of the drive voltage supply lines EVDD and EVSS. The first thin film transistor 210 can include a first semiconductor layer 211, a first insulating layer 212, a first gate electrode 213, a second insulating layer 214, a first source electrode 215, and a first drain electrode 216.

The first semiconductor layer 211 can be disposed near the substrate 105. The first semiconductor layer 211 can include a semiconductor material. For example, the first semiconductor layer 211 can include silicon. The first semiconductor layer 211 can include a polycrystalline semiconductor. For example, the first semiconductor layer 211 can include polysilicon or low-temperature polysilicon (LTPS), but embodiments of the present disclosure are not limited thereto. In another example, the first semiconductor layer 211 can include an oxide semiconductor. The first semiconductor layer 211 can include a first source region, a first drain region, and a first channel region. The first channel region can be disposed between the first source region and the first drain region. The first channel region can have lower electrical conductivity than that of the first source region and the first drain region. For example, the first source region and the first drain region can include a conductive impurity having a greater content than that of the first channel region.

The first insulating layer 212 can be disposed on the first semiconductor layer 211. The first insulating layer 212 can extend outwards beyond the first semiconductor layer 211. For example, a side surface of the first semiconductor layer 211 can be covered by the first insulating layer 212. The first insulating layer 212 can include an insulating material. For example, the first insulating layer 212 can include silicon oxide (SiOₓ) and/or silicon nitride (SiNₓ), but embodiments of the present disclosure are not limited thereto. The silicon oxide (SiOₓ) can include silicon dioxide (SiO₂). The first insulating layer 212 can include a material having high permittivity. For example, the first insulating material 212 can include a material such as hafnium oxide (HfO), but embodiments of the present disclosure are not limited thereto. The first insulating layer 212 can be a gate insulating layer, but embodiments of the present disclosure are not limited thereto.

The first gate electrode 213 can be disposed on the first insulating layer 212. The first gate electrode 213 can include a conductive material. For example, the first gate electrode 213 can include a single layer or multiple layers including one of aluminum (Al), chromium (Cr), copper (Cu), titanium (Ti), molybdenum (Mo), and tungsten (W) or an alloy thereof, but embodiments of the present disclosure are not limited thereto. The first gate electrode 213 can be insulated from the first semiconductor layer 211 by the first insulating layer 212. The first gate electrode 213 can overlap with the first channel region of the first semiconductor layer 211. For example, the first channel region of the first semiconductor layer 211 can have electrical conductivity corresponding to a voltage applied to the first gate electrode 213.

The second insulating layer 214 can be disposed on the first gate electrode 213. The second insulating layer 214 can extend outwards beyond the first gate electrode 213. For example, a side surface of the first gate electrode 213 can be covered by the second insulating layer 214. The second insulating layer 214 can extend along the first insulating layer 212. The second insulating layer 214 can include an insulating material. For example, the second insulating layer 214 can include silicon oxide (SiOₓ), but embodiments of the present disclosure are not limited thereto. The second insulating layer 214 can be an interlayer insulating layer, but embodiments of the present disclosure are not limited thereto.

The first source electrode 215 can be disposed on the second insulating layer 214. The first source electrode 215 can be insulated from the first gate electrode 213 by the second insulating layer 214. The first source electrode 215 can include a material different from that of the first gate electrode 213, but embodiments of the present disclosure are not limited thereto. The first source electrode 215 can include a conductive material. For example, the first source electrode 215 can include a single layer or multiple layers including one of aluminum (Al), chromium (Cr), copper (Cu), titanium (Ti), molybdenum (Mo), and tungsten (W) or an alloy thereof, but embodiments of the present disclosure are not limited thereto. The first source electrode 215 can be electrically connected to the first source region of the first semiconductor layer 211.

The first drain electrode 216 can be disposed on the second insulating layer 214. The first drain electrode 216 can include a conductive material. For example, the first drain electrode 216 can include a single layer or multiple layers including one of aluminum (Al), chromium (Cr), copper (Cu), titanium (Ti), molybdenum (Mo), and tungsten (W) or an alloy thereof, but embodiments of the present disclosure are not limited thereto. The first drain electrode 216 can be insulated from the first gate electrode 213 by the second insulating layer 214. The first drain electrode 216 can include a material different from that of the first gate electrode 213, but embodiments of the present disclosure are not limited thereto. For example, the first drain electrode 216 can include the same material as that of the first source electrode 215, but embodiments of the present disclosure are not limited thereto. The first drain electrode 216 can be formed using the same process as that of the first source electrode 215, but embodiments of the present disclosure are not limited thereto. The first drain electrode 216 can be electrically connected to the first drain region of the first semiconductor layer 211. The first drain electrode 216 can be spaced apart from the first source electrode 215.

Concrete positions of the first source electrode 215 and the first drain electrode 216 will be described later.

The second thin film transistor 220 can be electrically connected to the first thin film transistor 210. The second thin film transistor 220 can transmit a data signal to the first gate electrode 213 of the first thin film transistor 210 in accordance with a scan signal. For example, the second thin film transistor 220 can be disposed between the data line DL and the first gate electrode 213 of the first thin film transistor 210. The structure of the second thin film transistor 220 can be identical to the structure of the first thin film transistor 210, but embodiments of the present disclosure are not limited thereto. For example, the second thin film transistor 220 can include a second semiconductor layer 221, a fourth insulating layer 224, a second gate electrode 223, a second source electrode 225, and a second drain electrode 226.

The second semiconductor layer 221 can include a semiconductor material. The second semiconductor layer 221 can include a material identical to or different from that of the first semiconductor layer 221. For example, the second semiconductor layer 221 can include an oxide semiconductor such as indium-gallium-zinc oxide (IGZO), but embodiments of the present disclosure are not limited thereto. In another example, the second semiconductor layer 221 can include polysilicon or low-temperature polysilicon (LTPS).

The second semiconductor layer 221 can be disposed on a layer different from that of the first semiconductor layer 211. For example, a first protective layer 130 can be disposed on the second insulating layer 214, and the second semiconductor layer 221 can be disposed on the first protective layer 130. The first protective layer 130 can include silicon oxide (SiOₓ), silicon nitride (SiNₓ) or the like, but embodiments of the present disclosure are not limited thereto. In the display apparatus according to the embodiment of the present disclosure, accordingly, damage to the second semiconductor layer 221 caused by a formation process for the first semiconductor layer 211 can be prevented.

The second semiconductor layer 221 can include a second source region, a second drain region, and a second channel region. The second channel region can be disposed between the second source region and the second drain region. The second source region and the second drain region can have a lower resistance than that of the second channel region. For example, the second source region and the second drain region can include a region of oxide semiconductor treated to have conductivity. The second channel region can be a region of oxide semiconductor not treated to have conductivity.

The fourth insulating layer 224 can be disposed on the second semiconductor layer 221. The fourth insulating layer 224 can include an insulating material. The fourth insulating layer 222 can include the same material as that of the first insulating layer 212, but embodiments of the present disclosure are not limited thereto. For example, the fourth insulating layer 224 can have a multilayer structure, but embodiments of the present disclosure are not limited thereto.

The second gate electrode 223 can be disposed on the fourth insulating layer 224. For example, the second gate electrode 223 can overlap with the second channel region of the second semiconductor layer 221. The second gate electrode 223 can include a conductive material. For example, the second gate electrode 223 can include a single layer or multiple layers including one of aluminum (Al), chromium (Cr), copper (Cu), titanium (Ti), molybdenum (Mo), and tungsten (W) or an alloy thereof, but embodiments of the present disclosure are not limited thereto. The second gate electrode 223 can include the same material as that of the first gate electrode 213, but embodiments of the present disclosure are not limited thereto. The second gate electrode 223 can be insulated from the second semiconductor layer 221 by the fourth insulating layer 224. For example, the second channel region of the second semiconductor layer 221 can have electrical conductivity corresponding to a voltage applied to the second gate electrode 223.

A second protective layer 150 can be disposed on the fourth insulating layer 224. The second protective layer 150 can include silicon oxide (SiOₓ), silicon nitride (SiNₓ), or the like, but embodiments of the present disclosure are not limited thereto.

The second source electrode 225 can be disposed on the second protective layer 150. The second source electrode 225 can include a conductive material. For example, the second source electrode 225 can include aluminum (Al), chromium (Cr), copper (Cu), titanium (Ti), molybdenum (Mo), tungsten (W), or an alloy thereof, but embodiments of the present disclosure are not limited thereto. The second source electrode 225 can include the same material as that of the first source electrode 215, but embodiments of the present disclosure are not limited thereto. The second source electrode 225 can be insulated from the second gate electrode 223 by the fourth insulating layer 224. The second source electrode 225 can include a material different from that of the second gate electrode 223. The second source electrode 225 can be electrically connected to the second source region of the second semiconductor layer 221. For example, the fourth insulating layer 224 and the second protective layer 150 can include a second source contact hole configured to partially expose the second source region of the second semiconductor layer 221. The second source electrode 225 can include a region overlapping with the second source region of the second semiconductor layer 221. For example, the second source electrode 225 can contact the second source region of the second semiconductor layer 221 within the second source contact hole.

The second drain electrode 226 can be disposed on the second protective layer 150. The second drain electrode 226 can include a conductive material. For example, the second drain electrode 226 can include a single layer or a double layer including one of aluminum (Al), chromium (Cr), copper (Cu), titanium (Ti), molybdenum (Mo), and tungsten (W) or an alloy thereof, but embodiments of the present disclosure are not limited thereto. The second drain electrode 226 can include the same material as that of the first drain electrode 216, but embodiments of the present disclosure are not limited thereto. The second drain electrode 226 can be insulated from the second gate electrode 223 by the fourth insulating layer 224. The second drain electrode 226 can include a material different from that of the second gate electrode 223, but embodiments of the present disclosure are not limited thereto. For example, the second drain electrode 226 can include the same material as that of the second source electrode 225, but embodiments of the present disclosure are not limited thereto. The second drain electrode 226 can be formed using the same process as that of the second source electrode 225, but embodiments of the present disclosure are not limited thereto. The second drain electrode 226 can be electrically connected to the second drain region of the second semiconductor layer 221. The second drain electrode 226 can be spaced apart from the second source electrode 225. For example, the fourth insulating layer 224 and the second protective layer 150 can include a second drain contact hole configured to partially expose the second drain region of the second semiconductor layer 221. The second drain electrode 226 can include a region overlapping with the second drain region of the second semiconductor layer 221. For example, the second drain electrode 226 can contact the second drain region of the second semiconductor layer 221 within the second drain contact hole.

The second thin film transistor 220 can further include an auxiliary layer 232 under the second semiconductor layer 221. The auxiliary layer 232 can overlap with the second semiconductor layer 221. For example, the auxiliary layer 232 can include a single layer or multiple layers including one of aluminum (Al), chromium (Cr), copper (Cu), titanium (Ti), molybdenum (Mo), nickel (Ni), neodymium (Nd), and tungsten (W) or an alloy thereof, but embodiments of the present disclosure are not limited thereto. The auxiliary layer 232 can block light directed to the second semiconductor layer 221 and, as such, can extend the lifespan of the second thin film transistor 220. For example, the auxiliary layer 232 can be a light shielding layer, without being limited thereto. For example, in place of the auxiliary layer 232, an auxiliary layer can be configured under the first thin film transistor 210. The auxiliary layer can be disposed on a buffer layer 112. When the auxiliary layer is configured as described above, an insulating layer can be further configured on the buffer layer 112. The auxiliary layer can be constituted by the same material as that of the auxiliary layer 232, but embodiments of the present disclosure are not limited thereto. The auxiliary layer can block light directed to the first semiconductor layer 211 and, as such, can extend the lifespan of the first thin film transistor 210.

A buffer layer 110 can be disposed between the substrate 105 and the driving circuit of each pixel area PA. The buffer layer 110 can prevent contamination caused by the substrate 105 in a formation process for the driving circuits. For example, the buffer layer 110 can be disposed on the substrate 105. For example, the buffer layer 110 can cover the active area of the substrate 105. For example, the buffer layer 110 can completely cover the active area of the substrate 105. The buffer layer 110 can be disposed between the substrate 105 and the first semiconductor layer 211 of each pixel area PA. The buffer layer 110 can include an insulating material. For example, the buffer layer 110 can include an inorganic insulating material such as silicon oxide (SiOₓ) or silicon nitride (SiNₓ), but embodiments of the present disclosure are not limited thereto. The buffer layer 110 can have a multilayer structure, but embodiments of the present disclosure are not limited thereto. For example, the buffer layer 110 can include a stack structure including a buffer layer 111 and a second buffer layer which is the buffer layer 112 and includes a material different from that of the first buffer layer 111, but embodiments of the present disclosure are not limited thereto.

The first protective layer 130 can prevent damage to the first thin film transistor 210 caused by external impact and moisture. The first protective layer 130 can extend between the auxiliary layer 232 of each pixel area PA and the second semiconductor layer 221. In the display apparatus according to the embodiment of the present disclosure, accordingly, damage to the first thin film transistors 210 caused by external impact and moisture can be effectively prevented.

In each pixel region PA, the second protective layer 150 can be disposed between the fourth insulating layer 224 and the second source electrode 225 and between the fourth insulating layer 224 and the second drain electrode 226. The second protective layer 150 can prevent damage to the second semiconductor layer 221 caused by external impact and moisture. For example, the second protective layer 150 can extend outwards beyond the second semiconductor layer 221 along the fourth insulating layer 224. The second protective layer 150 can include a material different from that of the fourth insulating layer 224. For example, the fourth protective layer 150 can include silicon nitride (SiNₓ), but embodiments of the present disclosure are not limited thereto. In the display apparatus according to the embodiment of the present disclosure, accordingly, damage to the second semiconductor layer 221 caused by external impact and moisture can be effectively prevented.

The first source electrode 215 of the first thin film transistor 210 can be disposed on the second protective layer 150 in each pixel area PA. The first source electrode 215 can include a conductive material. For example, the first source electrode 215 can include a single layer or multiple layers including one of aluminum (Al), chromium (Cr), copper (Cu), titanium (Ti), molybdenum (Mo), and tungsten (W) or an alloy thereof, but embodiments of the present disclosure are not limited thereto. The first source electrode 215 can include a material different from that of the first gate electrode 213, but embodiments of the present disclosure are not limited thereto. The first source electrode 215 can be electrically connected to the first source region of the first semiconductor layer 211. For example, the first insulating layer 212, the second insulating layer 214, the first protective layer 130, the fourth insulating layer 224, and the second protective layer 150 can include a first source contact hole configured to partially expose the first source region of the first semiconductor layer 211. The first source electrode 215 can include a region overlapping with the first source region of the first semiconductor layer 211. For example, the first source electrode 215 can contact the first source region of the first semiconductor layer 211 within the first source contact hole.

The first drain electrode 216 of the first thin film transistor 210 can be disposed on the second protective layer 150 in each pixel area PA. The first drain electrode 216 can include a conductive material. For example, the first drain electrode 216 can include a single layer or multiple layers including one of aluminum (Al), chromium (Cr), copper (Cu), titanium (Ti), molybdenum (Mo), and tungsten (W) or an alloy thereof, but embodiments of the present disclosure are not limited thereto. The first drain electrode 216 can include a material different from that of the first gate electrode 213, but embodiments of the present disclosure are not limited thereto. For example, the first drain electrode 216 can include the same material as that of the first source electrode 215, but embodiments of the present disclosure are not limited thereto. The first drain electrode 216 can be formed using the same process as that of the first source electrode 215. The first drain electrode 216 can be electrically connected to the first drain region of the first semiconductor layer 211. The first drain electrode 216 can be spaced apart from the first source electrode 215. For example, the first insulating layer 212, the second insulating layer 214, the first protective layer 130, the fourth insulating layer 224, and the second protective layer 150 can include a first drain contact hole configured to partially expose the first drain region of the first semiconductor layer 211. The first drain electrode 216 can include a region overlapping with the first drain region of the first semiconductor layer 211. For example, the first drain electrode 216 can contact the first drain region of the first semiconductor layer 211 within the first drain contact hole.

The light emitting element 600 of each pixel area PA can be disposed on the transistor of the same pixel area PA. For example, the first thin film transistor 210 and the second thin film transistor 220 of each pixel area PA can be disposed between the substrate 105 and the first electrode 610 in the same pixel area PA. In the display apparatus according to the embodiment of the present disclosure, accordingly, the area occupied by each pixel area PA can be minimized. Accordingly, an enhancement in resolution can be achieved in the display apparatus according to the embodiment of the present disclosure.

A first planarization layer 160 and a second planarization layer 170 can be disposed between the driving circuit and the light emitting element 600 in each pixel area PA. For example, the first electrode 610, the emission layer 620, and the second electrode 630 in each pixel area PA can be disposed on the second planarization layer 170 in the same pixel area PA. The first planarization layer 160 and the second planarization layer 170 can reduce or remove steps formed by transistors. For example, an upper surface of the second planarization layer 170 facing the light emitting element 600 in each pixel area PA can be a flat surface. The first planarization layer 160 and the second planarization layer 170 can include an insulating material. For example, the first planarization layer 160 and the second planarization layer 170 can include an organic insulating material, but embodiments of the present disclosure are not limited thereto. The second planarization layer 170 can include a material different from that of the first planarization layer 160. In the display apparatus according to the embodiment of the present disclosure, accordingly, it can be possible to effectively reduce or remove steps formed by transistors.

An intermediate electrode 510 can be disposed between the first planarization layer 160 and the second planarization layer 170 in each pixel area PA. The light emitting element 600 can be electrically connected to the first drain electrode 216 of the first thin film transistor 210 through the intermediate electrode 510. For example, the intermediate electrode 510 can be connected to the first drain electrode 216 while extending through the first planarization layer 160, and the first electrode 610 of the light emitting element 600 can be connected to the intermediate electrode 510 while extending through the second planarization layer 170. The intermediate electrode 510 can include a region overlapping with the first drain electrode 216 and a region overlapping with the first electrode 610. For example, the intermediate electrode 510 can be disposed between the first drain electrode 216 and the first electrode 610. The intermediate electrode 510 can contact the first drain electrode 216. For example, the intermediate electrode 510 can directly contact the first drain electrode 216. The first electrode 610 can contact the intermediate electrode 510. For example, the first electrode 610 can directly contact the intermediate electrode 510. The intermediate electrode 510 can include a conductive material. For example, the intermediate electrode 510 can include a metal such as aluminum (Al), chromium (Cr), copper (Cu), titanium (Ti), molybdenum (Mo), or tungsten (W), but embodiments of the present disclosure are not limited thereto. The intermediate electrode 510 can include a material different from those of the first drain electrode 216 and the first electrode 610, but embodiments of the present disclosure are not limited thereto.

A bank 180 can be disposed on the second planarization layer 170 in each pixel area PA. The bank 180 can include an insulating material. For example, the bank 180 can be constituted by a material including a black pigment, etc., or an organic material such as a benzocyclobutene resin, a polyimide resin, an acryl resin, a photosensitive polymer, or the like, but embodiments of the present disclosure are not limited thereto. When the bank 180 is constituted by a material including a black pigment, a black dye, or the like, the bank 180 can be a black bank. When the bank 180 is constituted by a material including a black pigment or a black dye, the bank 180 can block light from an outside thereof and, as such, the display apparatus can achieve a greater enhancement in brightness. The bank 180 can include a material different from those of the first planarization layer 160 and the second planarization layer 170, but embodiments of the present disclosure are not limited thereto. The bank 180 can cover an edge of the first electrode 610. In each pixel area PA, the emission layer 620 and the second electrode 630 can be disposed on a portion of the first electrode 610 exposed by the bank 180. For example, the bank 180 can define an emission area within each pixel area PA.

A spacer 181 can be disposed on the bank 180 in each pixel area PA. The spacer 181 can be formed to have a smaller width than that of the bank 180. The spacer 181 can include an insulating material. For example, the spacer 181 can include an organic insulating material, but embodiments of the present disclosure are not limited thereto. The spacer 181 can be formed of the same material as that of the bank 180, but embodiments of the present disclosure are not limited thereto. The spacer 181 can prevent damage to the bank 180 and the emission material layer 622 formed on an adjacent pixel area PA due to a fine metal mask.

In each pixel area PA, the emission layer 620 can extend on and along the bank 180 and the spacer 181. Each pixel area PA can represent a color different from that of another pixel area PA adjacent thereto. For example, the emission material layer 622 of each pixel area PA can be separated from the emission material layer 622 of another pixel area PA adjacent to the former pixel area PA. The emission material layer 622 of each pixel area PA can include an end disposed within the same pixel area PA. The emission material layer 622 can be formed using a fine metal mask (FMM), but embodiments of the present disclosure are not limited thereto. The end of each emission layer 622 can be disposed on the bank 180 and the spacer 181. The first common layer 621 and the second common layer 623 of each pixel area PA can extend along a surface of the bank 180. For example, the first common layer 621 and the second common layer 623 of each pixel area PA can be connected to the first common layer 621 and the second common layer 623 of another pixel area PA adjacent to the former pixel area PA. In the display apparatus according to the embodiment of the present disclosure, accordingly, an enhancement in process efficiency can be achieved.

The voltage supplied to the second electrode 630 of each pixel area PA can be equal to the voltage supplied to the second electrode 630 of another pixel area PA adjacent to the former pixel area PA. For example, the second electrode 630 of each pixel area PA can be connected to the second electrode 630 of another pixel area PA adjacent to the bank 180. Accordingly, the display apparatus according to the embodiment of the present disclosure can control a brightness of each pixel area PA through a gate signal and a data signal applied to the same pixel area PA. The second electrode 630 of each pixel area PA can contact the second electrode 630 of another pixel area PA adjacent to the former pixel area PA.

An encapsulation member 700 can be disposed on the light emitting element 600 of each pixel area PA. The encapsulation member 700 can prevent damage to the light emitting elements 600 caused by external impact and moisture. The encapsulation member 700 can have a multilayer structure, but embodiments of the present disclosure are not limited thereto. For example, the encapsulation member 700 can include a first encapsulation layer 710, a second encapsulation layer 720, and a third encapsulation layer 730, but embodiments of the present disclosure are not limited thereto. Each of the first encapsulation layer 710, the second encapsulation layer 720, and the third encapsulation layer 730 can include an insulating material. The second encapsulation layer 720 can include a material different from that of the first encapsulation layer 710 and the third encapsulation layer 730, but embodiments of the present disclosure are not limited thereto. For example, the first encapsulation layer 710 and the third encapsulation layer 730 can include an inorganic insulating material, and the second encapsulation layer 720 can include an organic insulating material. Of course, embodiments of the present disclosure are not limited to the above-described conditions. In the display apparatus according to the embodiment of the present disclosure, accordingly, damage to the light emitting elements 600 caused by external impact and moisture can be effectively prevented. A step formed by the light emitting element 600 of each pixel area PA can be removed by the encapsulation member 700. For example, an upper surface of the encapsulation member 700 opposite to the substrate 105 can be a flat surface.

A touch part can be disposed on the encapsulation member 700. The touch part can sense touch of a user and/or a tool. For example, the touch part can include touch electrodes 811 and 822 and bridge electrodes 812. The touch electrodes 811 and 822 can be disposed in parallel. The bridge electrodes 812 can interconnect the touch electrodes 811 and 822. The touch electrodes 811 and 822 and the bridge electrodes 812 can include a conductive material. For example, the touch electrodes 811 and 822 and the bridge electrodes 812 can include a single layer or a double layer including one of aluminum (Al), chromium (Cr), copper (Cu), titanium (Ti), molybdenum (Mo), and tungsten (W) or an alloy thereof, but embodiments of the present disclosure are not limited thereto. The touch electrodes 811 and 822 and the bridge electrodes 812 can overlap with the active area of the substrate 105. In each pixel area PA, the light emitting element 600 can be disposed outside the touch electrodes 811 and 822 and the bridge electrodes 812. For example, the touch electrodes 811 and 822 and the bridge electrodes 812 can overlap with the bank 180. The touch electrodes 811 and 822 and the bridge electrodes 812 can be spaced apart from the light emitting element 600 in each pixel area PA. In the display apparatus according to the embodiment of the present disclosure, accordingly, light emitted in a direction perpendicular to an upper surface of the substrate 105 may not be blocked by the touch electrodes 811 and 822 and the bridge electrodes 812. In the display apparatus according to the embodiment of the present disclosure, accordingly, a reduction in brightness of each pixel area PA caused by the touch electrodes 811 and 822 and the bridge electrodes 812 can be prevented.

A touch insulating layer 830 can be disposed between each bridge electrode 812 and each of the touch electrodes 811 and 822. The touch insulating layer 830 can include an insulating material. For example, the touch insulating layer 830 can include a material such as silicon oxide (SiOₓ), silicon nitride (SiNₓ), or the like, but embodiments of the present disclosure are not limited thereto. The second touch electrodes 822 can be disposed on the same layer as that of the first touch electrodes 811, but embodiments of the present disclosure are not limited thereto. For example, the touch electrodes 811 and 822 and the bridge electrodes 812 interconnecting the touch electrodes 811 and 822 can be disposed on the touch insulating layer 830 covering the bridge electrodes 812. The touch insulating layer 830 can include touch contact holes configured to partially expose the bridge electrodes 812. Each touch electrode 811 can be connected to a corresponding one of the bridge electrodes 812 through a corresponding one of the touch contact holes.

A touch buffer layer 800 can be disposed between the encapsulation member 700 and the touch part 811, 812, 822. The touch buffer layer 800 can prevent damage to the encapsulation member 700 and the light emitting elements 600 caused by formation processes for the touch electrodes 811 and 822 and the bridge electrodes 812. The touch buffer layer 800 can include an insulating material. For example, the touch buffer layer 800 can include a material such as silicon oxide (SiOₓ), silicon nitride (SiNₓ), or the like, but embodiments of the present disclosure are not limited thereto.

An insulating layer 890 can be disposed on the touch part 811, 812, 822. The insulating layer 890 can prevent damage to the touch part 811, 812, 822 caused by external impact and moisture.

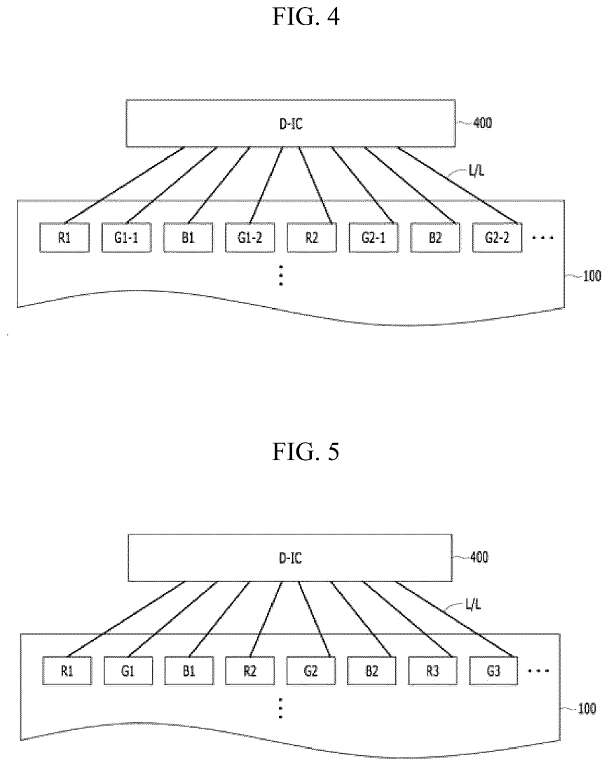

FIG. 4 is a diagram showing data link lines configured to interconnect a data driving IC and each of a plurality of sub-pixels of a display panel in a display apparatus according to an embodiment of the present disclosure.

FIG. 5 is a diagram showing data link lines configured to interconnect a data driving IC and each of a plurality of sub-pixels of a display panel in a display apparatus according to another embodiment of the present disclosure.

Particularly, FIG. 4 shows that a unit pixel is constituted by four sub-pixels R, G, B, and G, where a first red sub-pixel R1, a 1-1th green sub-pixel G1-1, a first blue sub-pixel B1, a 1-2th green sub-pixel G1-2, a second red sub-pixel R2, a 2-1th green sub-pixel G2-1, a second blue sub-pixel B2, a 2-2th green sub-pixel G2-2, a third red sub-pixel R3, a 3-1th green sub-pixel G3-1, etc. are disposed on one horizontal pixel line in this order, but embodiments of the present disclosure are not limited thereto.

FIG. 5 shows that a unit pixel is constituted by three sub-pixels R, G, and B, where a first red sub-pixel R1, a first green sub-pixel G1, a first blue sub-pixel B1, a second red sub-pixel R2, a second green sub-pixel G2, a second blue sub-pixel B2, a third red sub-pixel R3, a third green sub-pixel G3, a third blue sub-pixel B3, etc. are disposed on one horizontal pixel line in this order, but embodiments of the present disclosure are not limited thereto.

Referring to FIGS. 4 and 5, one data link line L/L can be disposed for each sub-pixel line extending in a vertical direction, in order to supply a data signal generated from each data driving IC D-IC of a data driving circuit 400 to each sub-pixel of a display panel 100.

In addition, a maximum number of data link lines should be disposed in a limited space of the display panel 100 and, as such, the data link lines can be disposed using at least two metal layers in order to thinly and densely dispose the data link lines.

When the data link lines are disposed using two metal layers, three metal layers, or four metal layers, the metal layers can be constituted by at least two, three, or four of a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

In order to compensate for brightness deviations among pixels in the display panel 100, a data voltage meeting a target brightness and an initial brightness can be calculated through a camera compensation procedure, and the calculated data voltage can then be applied. Such compensation can be performed on a minimum-area basis without being performed on an all-pixel basis, for a reduction in brightness loss and/or security of mass production. Accordingly, the same data voltage should be applied in a minimum area for camera compensation.

When data link lines are configured using two, three or more metal layers having a height difference or a step among a plurality of metal layers, an overlay capacitance can be formed because an overlap region between the metal layers is present and, as such, can influence an applied AC data voltage. As a result, voltage fluctuation can occur.

For example, when data link lines for each of red (R), green (G), and blue (B), to which the same data voltage should be applied, have different capacitances at different pixels, respectively, and such a capacitance difference among the data link lines occurs periodically, fine vertical line defects, which cannot be solved even through camera compensation, can be generated.

Accordingly, the data link lines L/L can be disposed such that overlay capacitance differences among the data link lines L/L are periodically repeated in accordance with kinds of sub-pixels and numbers of sub-pixels in order to enable the data link lines L/L connected to sub-pixel lines of the same color to have the same overlay capacitance at all sub-pixels. When the number of metal layers of the data link lines L/L is greater than the number of sub-pixel lines, the overlap area of the metal layers and the distance between the metal layers can be adjusted such that the number of different capacitances is equal to or smaller than the number of sub-pixel lines. In the present disclosure, the data link lines L/L can be disposed such that the overlap capacitances thereof are equal among the sub-pixel lines of the same color, even though an overlay capacitance difference of the data link lines L/L is generated among the sub-pixel lines.

The data link lines L/L can be disposed in accordance with the number of sub-pixels constituting a unit pixel and the number of metal layers used as the data link lines L/L, but embodiments of the present disclosure are not limited thereto.

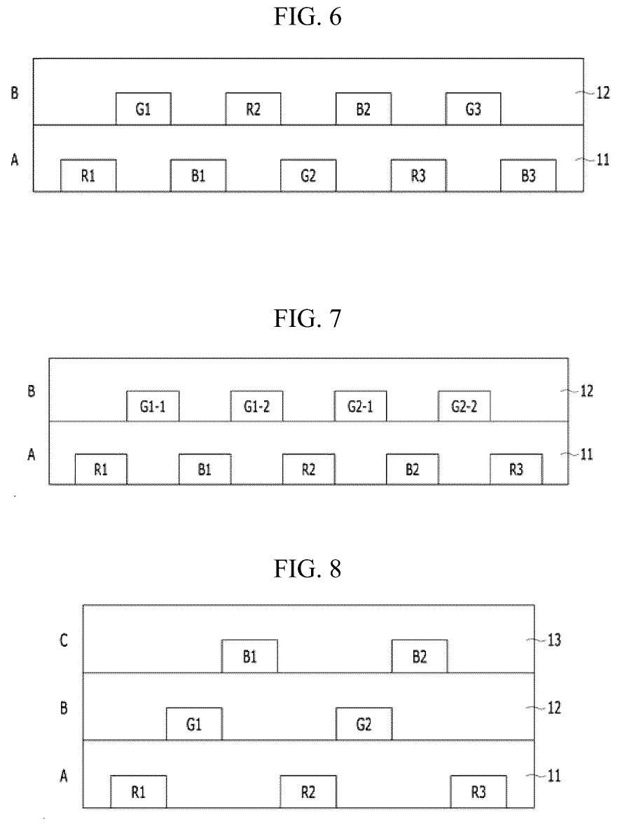

FIG. 6 is a sectional view showing disposition of data link lines in a display apparatus according to an embodiment of the present disclosure.

Although FIG. 6 shows the case in which the number of sub-pixels constituting a unit pixel is three (R, G, and B), and the number of metal layers used as data link lines is two, embodiments of the present disclosure are not limited thereto.

When data link lines are configured using two metal layers, the two metal layers can be constituted by two metal layers among a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

Referring to FIG. 6, for example, each unit pixel can be constituted by a red sub-pixel R, a green sub-pixel G, and a blue sub-pixel B, where a first red sub-pixel R1, a first green sub-pixel G1, a first blue sub-pixel B1, a second red sub-pixel R2, a second green sub-pixel G2, a second blue sub-pixel B2, a third red sub-pixel R3, a third green sub-pixel G3, and a third blue sub-pixel B3 can be disposed on one horizontal pixel line in this order.

In addition, one or more first data link lines can be disposed at one of the two layers, for example, a first layer A. The one or more first data link lines can be disposed while having a uniform spacing thereamong. At the other of the two layers, for example, a second layer B, one or more second data link lines can be disposed among groups each including one or more of the first data link lines.

In accordance with the present disclosure, when each unit pixel includes three sub-pixels R, G, and B, and the data link lines are configured using two metal layers, first data link lines of the first red sub-pixel R1, the first blue sub-pixel B1, the second green sub-pixel G2, the third red sub-pixel R3, and the third blue sub-pixel B3 can be disposed at the first layer A of the two layers. In addition, at the second layer B of the two layers, second data link lines of the first green sub-pixel G1, the second red sub-pixel R2, the second blue sub-pixel B2, and the third green sub-pixel G3 can be disposed.

For example, at the first layer A, one or more first data link lines each constituted by the metal layer identical to the first gate electrode 213 described with reference to FIG. 3 can be disposed. At the second layer B, one or more second data link lines each constituted by the metal layer identical to the auxiliary layer 232 described with reference to FIG. 3 can be disposed among groups each including one or more of the first data link lines. In addition, the one or more first data link lines can be electrically connected to a data line of the first red sub-pixel R1, a data line of the first blue sub-pixel B1, a data line of the second green sub-pixel G2, a data line of the third red sub-pixel R3, and a data line of the third blue sub-pixel B3, respectively. The one or more second data link lines can be electrically connected to a data line of the first green sub-pixel G1, a data line of the second red sub-pixel R2, a data line of the second blue sub-pixel B2, and a data line of the third green sub-pixel G3, respectively.

The one or more second data link lines disposed at the second layer B may not overlap with the one or more first data link lines disposed at the first layer A. For example, the one or more second data link lines disposed at the second layer B can be disposed among groups each including one or more of the first data link lines. In addition, the one or more second data link lines disposed at the second layer B can overlap with respective first data link lines adjacent thereto among the one or more first data link lines disposed at the first layer A while having the same overlap area.

The one or more first data link lines disposed at the first layer A can be electrically isolated or insulated from the one or more second data link lines disposed at the second layer B by insulating layers 11 and 12, respectively.

Accordingly, the data link lines can be configured to have the same overlay capacitance for different sub-pixels, without restriction of an overlay capacitance difference thereamong.

FIG. 7 is a sectional view showing disposition of data link lines in a display apparatus according to another embodiment of the present disclosure.

Particularly, FIG. 7 shows the case in which the number of sub-pixels constituting a unit pixel is four (R, G, B, and G), and the number of metal layers used as data link lines is two.

When data link lines are configured using two metal layers, the two metal layers can be constituted by two metal layers among a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

Referring to FIG. 7, for example, each unit pixel can be constituted by a red sub-pixel R, a green sub-pixel G, a blue sub-pixel B, and a green sub-pixel G, where a first red sub-pixel R1, a 1-1th green sub-pixel G1-1, a first blue sub-pixel B1, a 1-2th green sub-pixel G1-2, a second red sub-pixel R2, a 2-1th green sub-pixel G2-1, a second blue sub-pixel B2, a 2-2th green sub-pixel G2-2, and a third red sub-pixel R3 can be disposed on one horizontal pixel line in this order.

In addition, one or more first data link lines can be disposed at a first layer A. The one or more first data link lines can be disposed while having a uniform spacing thereamong. At a second layer B, one or more second data link lines can be disposed among groups each including one or more of the first data link lines.

Accordingly, when each unit pixel includes four sub-pixels R, G, B, and G, and the data link lines are configured using two metal layers, first data link lines of the first red sub-pixel R1, the first blue sub-pixel B1, the second red sub-pixel R2, the second blue sub-pixel B2, and the third red sub-pixel R3 can be disposed at the first layer A. In addition, at the second layer B, the 1-1th green sub-pixel G1-1, the 1-2th green sub-pixel G1-2, the 2-1th green sub-pixel G2-1, and the 2-2th green sub-pixel G2-2 can be disposed.

For example, at the first layer A, one or more first data link lines each constituted by the metal layer identical to the first gate electrode 213 described with reference to FIG. 3 can be disposed. At the second layer B, one or more second data link lines each constituted by the metal layer identical to the auxiliary layer 232 described with reference to FIG. 3 can be disposed among groups each including one or more of the first data link lines. In addition, the one or more first data link lines can be electrically connected to a data line of the first red sub-pixel R1, a data line of the first blue sub-pixel B1, a data line of the second red sub-pixel R2, a data line of the second blue sub-pixel B2, and a data line of the third red sub-pixel R3, respectively. The one or more second data link lines can be electrically connected to a data line of the 1-1th green sub-pixel G1-1, a data line of the 1-2th green sub-pixel G1-2, a data line of the 2-1th green sub-pixel G2-1, and a data line of the 2-2th green sub-pixel G2-2, respectively.

The one or more second data link lines disposed at the second layer B may not overlap with the one or more first data link lines disposed at the first layer A. For example, the one or more second data link lines disposed at the second layer B can be disposed among groups each including one or more of the first data link lines. In addition, the one or more second data link lines disposed at the second layer B can overlap with respective first data link lines adjacent thereto among the one or more first data link lines disposed at the first layer A while having the same overlap area.

The one or more first data link lines disposed at the first layer A can be electrically isolated or insulated from the one or more second data link lines disposed at the second layer B by insulating layers 11 and 12, respectively.

Although the embodiment in which each unit pixel is constituted by a red sub-pixel R, a green sub-pixel G, a blue sub-pixel B, and a green sub-pixel G has been described with reference to FIG. 7, one of the two green sub-pixels can be substituted by a white sub-pixel.

Accordingly, the data link lines can be configured to have the same overlay capacitance for different sub-pixels, without restriction of an overlay capacitance difference thereamong.

In accordance with the present disclosure, when data link lines are configured using by two metal layers, data lines of odd sub-pixels disposed on one horizontal pixel line can be connected to a data driving IC by data link lines disposed at the first layer A, and data lines of even sub-pixels disposed on the one horizontal pixel line can be connected to the data driving IC by data link lines disposed at the second layer B, in accordance with an order of sub-pixels disposed on the one horizontal pixel line, irrespective of whether each unit pixel is constituted by three sub-pixels or four sub-pixels.

In accordance with the present disclosure, when data link lines are configured using two metal layers, data lines of odd sub-pixels disposed on one horizontal pixel line can be connected to the data driving IC by data link lines disposed at the second layer B, and data lines of even sub-pixels disposed on the one horizontal pixel line can be connected to the data driving IC by data link lines disposed at the first layer A, in accordance with an order of sub-pixels disposed on the one horizontal pixel line, irrespective of whether each unit pixel is constituted by three sub-pixels or four sub-pixels.

For example, when data link lines are configured using two metal layers, data lines of odd sub-pixels disposed on one horizontal pixel line can be connected to the data driving IC by data link lines disposed at one of two layers among data link lines disposed at the two layers, and data lines of even sub-pixels disposed on the one horizontal pixel line can be connected to the data driving IC by data link lines disposed at the remaining one of the two layers among the data link lines disposed at the two layers, irrespective of whether each unit pixel is constituted by three sub-pixels or four sub-pixels.

FIG. 8 is a sectional view showing disposition of data link lines in a display apparatus according to another embodiment of the present disclosure.

Particularly, FIG. 8 shows the case in which the number of sub-pixels constituting a unit pixel is three (R, G, and B), and the number of metal layers of data link lines is three.

When data link lines are configured using three metal layers, the three metal layers can be constituted by three metal layers among a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

Referring to FIG. 8, for example, each unit pixel can be constituted by a red sub-pixel R, a green sub-pixel G, and a blue sub-pixel B, where a first red sub-pixel R1, a first green sub-pixel G1, a first blue sub-pixel B1, a second red sub-pixel R2, a second green sub-pixel G2, a second blue sub-pixel B2, and a third red sub-pixel R3 can be disposed on one horizontal pixel line in this order.

In addition, one or more first data link lines can be disposed at a first layer A. The one or more first data link lines can be disposed while having a uniform spacing thereamong. At a second layer B, one or more second data link lines can be disposed among groups each including one or more of the first data link lines. At a third layer C, one or more third data link lines can be disposed among groups each including one or more of the first data link lines and one or more of the second data link lines. For example, one second data link line and one third data link line can be disposed between adjacent ones of the first data link lines. One first data link line and one third data link line can be disposed between adjacent ones of the second data link lines. One first data link line and one second data link line can be disposed between adjacent ones of the third data link lines.

In accordance with the present disclosure, when each unit pixel includes three sub-pixels R, G, and B, and the number of metal layers used for data link lines is three, first data link lines of the first red sub-pixel R1, the second red sub-pixel R2, and the third red sub-pixel R3 can be disposed at the first layer A.

At the second layer B, second data link lines of the first green sub-pixel G1 and the second green sub-pixel G2 can be disposed.

At the third layer C, third data link lines of the first blue sub-pixel B1 and the second blue sub-pixel B2 can be disposed.

For example, one or more first data link lines each constituted by the metal layer identical to the first gate electrode 213 described with reference to FIG. 3 can be disposed at the first layer A. At the second layer B, one or more second data link lines each constituted by the metal layer identical to the auxiliary layer 232 described with reference to FIG. 3 can be disposed. At the third layer C, one or more third data link lines each constituted by the metal layer identical to the second gate electrode 223 described with reference to FIG. 3 can be disposed.

The one or more first data link lines can be electrically connected to a data line of the first red sub-pixel R1, a data line of the second red sub-pixel R2, and a data line of the third red sub-pixel R3, respectively.

The one or more second data link lines can be electrically connected to a data line of the first green sub-pixel G1 and a data line of the second green sub-pixel G2, respectively.

The one or more third data link lines can be electrically connected to a data line of the first blue sub-pixel B1 and a data line of the second blue sub-pixel B2, respectively.

In accordance with the present disclosure, the one or more first data link lines can be disposed at the first layer A. The one or more second data link lines can be disposed at the second layer B among groups each including one or more of the first data link lines. The one or more third data link lines can be disposed at the third layer C among groups each including adjacent ones of the first data link lines and the second data link lines.

The one or more first data link lines, the one or more second data link lines, and the one or more third data link lines disposed at respective layers may not overlap with one another. For example, the one or more second data link lines disposed at the second layer B can be disposed among groups each including one or more of the first data link lines disposed at the first layer A. For example, the one or more third data link lines disposed at the third layer C can be disposed among groups each including one or more of the first data link lines disposed at the first layer A. For example, the one or more third data link lines disposed at the third layer C can be disposed among groups each including one or more of the second data link lines disposed at the second layer B. In addition, adjacent ones of the first to third data link lines disposed at respective layers can overlap each other while having the same overlap area.

The one or more first data link lines disposed at the first layer A, the one or more second data link lines disposed at the second layer B, and the one or more third data link lines disposed at the third layer C can be electrically isolated or insulated from one another by insulating layers 11, 12, and 13, respectively.

Accordingly, the data link lines can be configured to have the same overlay capacitance for different sub-pixels, without restriction of an overlay capacitance difference thereamong.

In accordance with the present disclosure, when data link lines are configured using three metal layers, and unit pixels each includes three sub-pixels R, G, and B, data lines of first sub-pixels R of the unit pixels can be connected to a data driving IC by data link lines disposed at the first layer A, data lines of second sub-pixels G of the unit pixels can be connected to the data driving IC by data link lines disposed at the second layer B, and data lines of third sub-pixels B of the unit pixels can be connected to the data driving IC by data link lines disposed at the third layer C.

For example, the first sub-pixels R of the unit pixels can be connected to the data driving IC by the data link lines disposed at one of three layers among the data link lines disposed at the three layers, the second sub-pixels G of the unit pixels can be connected to the data driving IC by the data link lines disposed at another one of the three layers among the data link lines disposed at the three layers, and the third sub-pixels B of the unit pixels can be connected to the data driving IC by the data link lines disposed at the remaining one of the three layers among the data link lines disposed at the three layers.

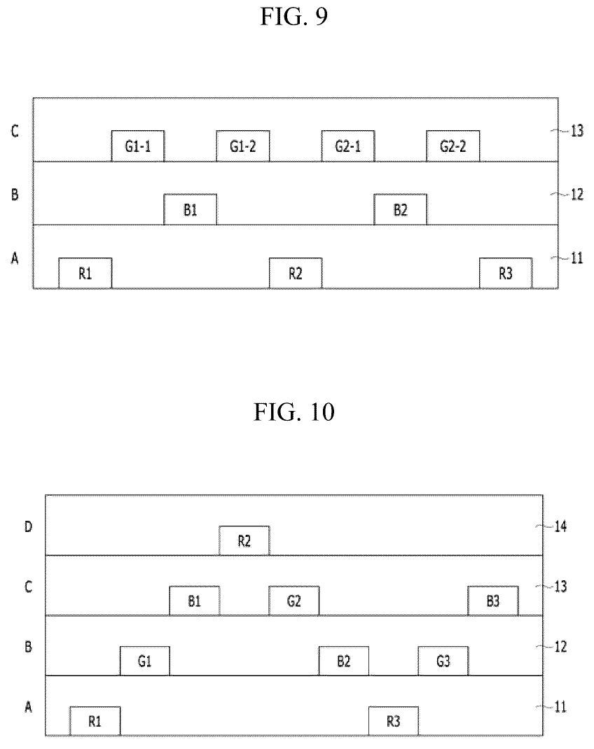

FIG. 9 is a sectional view showing disposition of data link lines in a display apparatus according to another embodiment of the present disclosure.

Particularly, FIG. 9 shows the case in which the number of sub-pixels constituting a unit pixel is four (R, G, B, and G), and the number of metal layers used for data link lines is three.

When the data link lines are configured using three metal layers, the three metal layers can be constituted by three metal layers among a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

Referring to FIG. 9, for example, each unit pixel can be constituted by a red sub-pixel R, a green sub-pixel G, a blue sub-pixel B, and a green sub-pixel G, where a first red sub-pixel R1, a 1-1th green sub-pixel G1-1, a first blue sub-pixel B1, a 1-2th green sub-pixel G1-2, a second red sub-pixel R2, a 2-1th green sub-pixel G2-1, a second blue sub-pixel B2, a 2-2th green sub-pixel G2-2, and a third red sub-pixel R3 can be disposed on one horizontal pixel line in this order.

One or more first data link lines can be disposed at a first layer A. The one or more first data link lines can be disposed while having a uniform spacing thereamong. At a second layer B, one or more second data link lines can be disposed among groups each including one or more of the first data link lines. At a third layer C, one or more third data link lines can be disposed among groups each including one or more of the first data link lines and one or more of the second data link lines. For example, one second data link line and one third data link line can be disposed between adjacent ones of the first data link lines. One first data link line and one third data link line can be disposed between adjacent ones of the second data link lines. One first data link line and one second data link line can be disposed between adjacent ones of the third data link lines.

In accordance with the present disclosure, when each unit pixel includes four sub-pixels R, G, B, and G, and data link lines are configured using three metal layers, first data link lines of the first red sub-pixel R1, the second red sub-pixel R2, and the third red sub-pixel R3 can be disposed at the first layer A.

At the second layer B, second data link lines of the first blue sub-pixel B1 and the second blue sub-pixel B2 can be disposed.

At the third layer C, third data link lines of the 1-1th green sub-pixel G1-1, the 1-2th green sub-pixel G1-2, the 2-1th green sub-pixel G2-1, and the 2-2th green sub-pixel G2-2 can be disposed.

For example, one or more first data link lines each constituted by the metal layer identical to the first gate electrode 213 described with reference to FIG. 3 can be disposed at the first layer A. At the second layer B, one or more second data link lines each constituted by the metal layer identical to the auxiliary layer 232 described with reference to FIG. 3 can be disposed. At the third layer C, one or more third data link lines each constituted by the metal layer identical to the second gate electrode 223 described with reference to FIG. 3 can be disposed.

The one or more first data link lines can be electrically connected to a data line of the first red sub-pixel R1, a data line of the second red sub-pixel R2, and a data line of the third red sub-pixel R3, respectively.

The one or more second data link lines can be electrically connected to a data line of the first blue sub-pixel B1 and a data line of the second blue sub-pixel B2, respectively.

The one or more third data link lines can be electrically connected to a data line of the 1-1th green sub-pixel G1-1, a data line of the 1-2th green sub-pixel G1-2, a data line of the 2-1th green sub-pixel G2-1, and a data line of the 2-2th green sub-pixel G2-2, respectively.

In accordance with the present disclosure, one or more first data link lines can be disposed at the first layer A, one or more second data link lines can be disposed at the second layer B among groups each including one or more of the first data link lines, and one or more third data link lines can be disposed at the third layer C among groups each including adjacent ones of the first data link lines and the second data link lines.

The one or more first data link lines, the one or more second data link lines, and the one or more third data link lines disposed at respective layers may not overlap one another. For example, the one or more second data link lines disposed at the second layer B can be disposed among groups each including one or more of the first data link lines disposed at the first layer A. For example, the one or more third data link lines disposed at the third layer C can be disposed among groups each including one or more of the first data link lines disposed at the first layer A. For example, the one or more second data link lines disposed at the second layer B can be disposed among groups each including one or more of the third data link lines disposed at the third layer C. In addition, the first to third data link links disposed at respective layers can overlap with the data link lines adjacent thereto while having the same overlap area.

Each of the one or more first data link lines disposed at the first layer A, each of the one or more second data link lines disposed at the second layer B, and each of the one or more third data link lines disposed at the third layer C can be electrically isolated or insulated from one another by insulating layers 11, 12, and 13.

Although the embodiment in which each unit pixel is constituted by a red sub-pixel R, a green sub-pixel G, a blue sub-pixel B, and a green sub-pixel G has been described with reference to FIG. 9, one of the two green sub-pixels can be substituted by a white sub-pixel.

Accordingly, the data link lines can be configured to have the same overlay capacitance for different sub-pixels, without restriction of an overlay capacitance difference thereamong.

In accordance with the present disclosure, when data link lines are configured using three metal layers, and unit pixels each includes four sub-pixels R, G, B, and G, first sub-pixels R of the unit pixels can be connected to a data driving IC by data link lines disposed at the first layer A, third sub-pixels B of the unit pixels can be connected to the data driving IC by data link lines disposed at the second layer B, and second and fourth sub-pixels G of the unit pixels can be connected to the data driving IC by data link lines disposed at the third layer C.

For example, when data link lines are configured using three metal layers, and unit pixels each includes four sub-pixels R, G, B, and G, the first sub-pixels R of the unit pixels can be connected to the data driving IC by the data link lines disposed at one of the three layers among the data link lines disposed at the three layers, the third sub-pixels B of the unit pixels can be connected to the data driving IC by the data link lines disposed at another one of the three layers among the data link lines disposed at the three layers, and the second and fourth sub-pixels G of the unit pixels can be connected to the data driving IC by the data link lines disposed at the remaining one of the three layers among the data link lines disposed at the three layers.

FIG. 10 is a sectional view showing disposition of data link lines in a display apparatus according to another embodiment of the present disclosure.

Particularly, FIG. 10 shows the case in which the number of sub-pixels constituting a unit pixel is four (R, G, B, and G), and the number of metal layers used for data link lines is four.

When data link lines are configured using four metal layers, the four metal layers can be constituted by four metal layers among a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

Referring to FIG. 10, for example, each unit pixel can be constituted by a red sub-pixel R, a green sub-pixel G, and a blue sub-pixel B, where a first red sub-pixel R1, a first green sub-pixel G1, a first blue sub-pixel B1, a second red sub-pixel R2, a second green sub-pixel G2, a second blue sub-pixel B2, a third red sub-pixel R3, a third green sub-pixel G3, and a third blue sub-pixel B3 can be disposed on one horizontal pixel line in this order.

In addition, one or more first data link lines can be disposed at a first layer A. The one or more first data link lines can be disposed while having a uniform spacing thereamong. At a second layer B, one or more second data link lines can be disposed among groups each including one or more of the first data link lines. At a third layer C, one or more third data link lines can be disposed among groups each including one or more of the first data link lines and one or more of the second data link lines. At a fourth layer D, one or more fourth data link lines can be disposed among groups each including one or more of the third data link lines. For example, two second data link lines, two third data link lines, and one fourth data link line can be disposed between adjacent ones of the first data link lines. Two third data link lines and one fourth data link line can be disposed between adjacent ones of the second data link lines. One fourth data link line can be disposed between adjacent ones of the third data link lines.

In accordance with the present disclosure, when each unit pixel includes three sub-pixels R, G, and B, and data link lines are configured using four metal layers, first data link lines of the first red sub-pixel R1 and the third red sub-pixel R3 can be disposed at the first layer A.

At the second layer B, second data link lines of the first green sub-pixel G1, the second blue sub-pixel B2, and the third green sub-pixel G3 can be disposed.

At the third layer C, third data link lines of the first blue sub-pixel B1, the second green sub-pixel G2, and the third blue sub-pixel B3 can be disposed.

At the fourth layer D, fourth data link lines of the second red sub-pixel R2 can be disposed.

For example, one or more first data link lines each constituted by the metal layer identical to the first gate electrode 213 described with reference to FIG. 3 can be disposed at the first layer A. At the second layer B, one or more second data link lines each constituted by the metal layer identical to the auxiliary layer 232 described with reference to FIG. 3 can be disposed. At the third layer C, one or more third data link lines each constituted by the metal layer identical to the second gate electrode 223 described with reference to FIG. 3 can be disposed. At the fourth layer D, one or more fourth data link lines each constituted by the metal layer identical to the source and drain electrodes 215, 216, 225, and 226 described with reference to FIG. 3 can be disposed.

The one or more first data link lines can be electrically connected to a data line of the first red sub-pixel R1 and a data line of the third red sub-pixel R3, respectively.

The one or more second data link lines can be electrically connected to a data line of the green sub-pixel G1, a data line of the second blue sub-pixel B2, and a data line of the third green sub-pixel G3, respectively.

The one or more third data link lines can be electrically connected to a data line of the first blue sub-pixel B1, a data line of the second green sub-pixel G2, and a data line of the third blue sub-pixel B3, respectively.

The one or more fourth data link lines can be electrically connected to a data line of the second red sub-pixel R2.

In accordance with the present disclosure, one or more first data link lines can be disposed at the first layer A. At the second layer B, two second data link lines can be disposed at the second layer B between adjacent ones of the first data link lines. At the third layer C, two third data link lines can be disposed between adjacent ones of the second data link lines. At the fourth layer D, one fourth data link line can be disposed between adjacent ones of the second data link lines.

The one or more first data link lines, the one or more second data link lines, the one or more third data link lines, and the one or more fourth data link lines disposed at respective layers may not overlap one another. For example, the one or more second data link lines disposed at the second layer B can be disposed among groups each including one or more of the first data link lines disposed at the first layer A. For example, the one or more third data link lines disposed at the third layer C can be disposed among groups each including one or more of the first data link lines disposed at the first layer A. For example, the one or more third data link lines disposed at the third layer C can be disposed among groups each including one or more of the second data link lines disposed at the second layer B. For example, the one or more fourth data link lines disposed at the fourth layer D can be disposed among groups each including one or more of the third data link lines disposed at the third layer C. In addition, the first to fourth data link lines disposed at respective layers can overlap with the data link lines adjacent thereto while having the same overlap area.

Each of the one or more first data link lines disposed at the first layer A, each of the one or more second data link lines disposed at the second layer B, each of the one or more third data link lines disposed at the third layer C, and each of the one or more fourth data link lines disposed at the fourth layer D can be electrically isolated or insulated from one another by insulating layers 11, 12, 13, and 14.

Accordingly, the data link lines can be configured to have the same overlay capacitance for different sub-pixels, without restriction of an overlay capacitance difference thereamong.

In accordance with the present disclosure, when data link lines are configured using four metal layers, and unit pixels each includes three sub-pixels, in accordance with an order of data lines of sub-pixels disposed on one horizontal pixel line, data lines of first, seventh, and thirteenth ones of the sub-pixels disposed on the one horizontal pixel line can be connected to a data driving IC by data link lines disposed at the first layer A, second, sixth, eighth, twelfth, and fourteenth ones of the sub-pixels disposed on the one horizontal pixel line can be connected to the data driving IC by data link lines disposed at the second layer B, third, fifth, ninth, eleventh, and fifteenth ones of the sub-pixels disposed on the one horizontal pixel line can be connected to the data driving IC by data link lines disposed at the third layer B, and fourth, tenth, and sixteenth ones of the sub-pixels disposed on the one horizontal pixel line can be connected to the data driving IC by data link lines disposed at the fourth layer D.

For example, when data link lines are configured using four metal layers, and unit pixels each includes three sub-pixels, the data lines of the sub-pixels disposed on the one horizontal pixel line can be connected to the data driving IC by data link lines disposed at metal layers of an ascending or descending order, respectively, in accordance with an order of the sub-pixels.

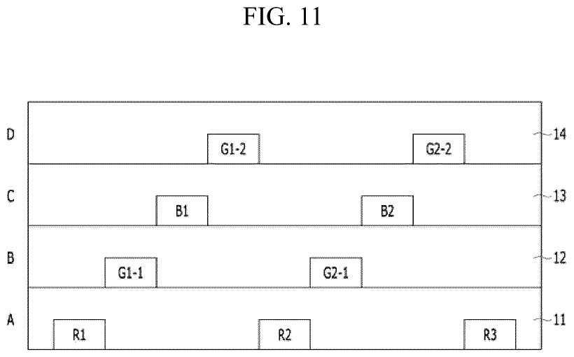

FIG. 11 is a sectional view showing disposition of data link lines in a display apparatus according to another embodiment of the present disclosure.

Particularly, FIG. 11 shows the case in which the number of sub-pixels constituting a unit pixel is four (R, G, B, and G), and the number of metal layers used for data link lines is four.

When data link lines are configured using four metal layers, the four metal layers can be constituted by four metal layers among a metal layer identical to the first gate electrode 213 described with reference to FIG. 3, a metal layer identical to the auxiliary layer 232 described with reference to FIG. 3, a metal layer identical to the second gate electrode 223 described with reference to FIG. 3, a metal layer identical to the source and drain electrodes 215, 216, 225, and 226 described with reference to FIG. 3, and a metal layer identical to the intermediate electrode 510 described with reference to FIG. 3.

Referring to FIG. 11, for example, each unit pixel can be constituted by a red sub-pixel R, a green sub-pixel G, a blue sub-pixel B, and a green sub-pixel G, where a first red sub-pixel R1, a 1-1th green sub-pixel G1-1, a first blue sub-pixel B1, a 1-2th green sub pixel G1-2, a second red sub-pixel R2, a 2-1th green sub-pixel G2-1, a second blue sub-pixel B2, a 2-2th green sub-pixel G2-2, and a third red sub-pixel R3 can be disposed on one horizontal pixel line in this order.

In addition, one or more first data link lines can be disposed at a first layer A. The one or more first data link lines can be disposed while having a uniform spacing thereamong. At a second layer B, one or more second data link lines can be disposed among groups each including one or more of the first data link lines. At a third layer C, one or more third data link lines can be disposed among groups each including one or more of the first data link lines and one or more of the second data link lines. At a fourth layer D, one or more fourth data link lines can be disposed among groups each including one or more of the third data link lines. For example, one second data link line, one third data link line, and one fourth data link line can be disposed between adjacent ones of the first data link lines. One third data link line and one fourth data link line can be disposed between adjacent ones of the second data link lines. One fourth data link line can be disposed between adjacent ones of the third data link lines.

In accordance with the present disclosure, when unit pixels each includes four sub-pixels R, G, B, and G, and data link lines are configured using four metal layers, first data link lines of the first red sub-pixel R1, the second red sub-pixel R2, and the third red sub-pixel R3 can be disposed at the first layer A.

At the second layer B, second data link lines of the 1-1th green sub-pixel G1-1 and the 2-1th green sub-pixel G2-1 can be disposed.

At the third layer C, third data link lines of the first blue sub-pixel B1 and the second blue sub-pixel B2 can be disposed.

At the fourth layer D, fourth data link lines of the 1-2th green sub-pixel G1-2 and the 2-2th green sub-pixel G2-2 can be disposed.

For example, one or more first data link lines each constituted by the metal layer identical to the first gate electrode 213 described with reference to FIG. 3 can be disposed at the first layer A. At the second layer B, one or more second data link lines each constituted by the metal layer identical to the auxiliary layer 232 described with reference to FIG. 3 can be disposed. At the third layer C, one or more third data link lines each constituted by the metal layer identical to the second gate electrode 223 described with reference to FIG. 3 can be disposed. At the fourth layer D, one or more fourth data link lines each constituted by the metal layer identical to the source and drain electrodes 215, 216, 225, and 226 described with reference to FIG. 3 can be disposed.

The one or more first data link lines can be electrically connected to a data line of the first red sub-pixel R1, a data line of the second red sub-pixel R2, and a data line of the third red sub-pixel R3, respectively.

The one or more second data link lines can be electrically connected to a data line of the 1-1th green sub-pixel G1-1 and a data line of the 2-1th green sub-pixel G2-1, respectively.

The one or more third data link lines can be electrically connected to a data line of the first blue sub-pixel B1 and a data line of the second blue sub-pixel B2, respectively.

The one or more fourth data link lines can be electrically connected to a data line of the 1-2th green sub-pixel G1-2 and a data line of the 2-2th green sub-pixel G2-2.

In accordance with the present disclosure, one or more first data link lines can be disposed at the first layer A. The one or more first data link lines can be disposed while having a uniform spacing thereamong. A plurality of second data link lines can be disposed at the second layer B such that one second data link line is disposed between adjacent ones of the first data link lines. A plurality of third data link lines can be disposed at the third layer C such that one third data link line is disposed between adjacent ones of the second data link lines. A plurality of fourth data link lines can be disposed at the fourth layer D such that one fourth data link line is disposed among groups each including adjacent ones of the third data link lines and the first data link lines.

The one or more first data link lines, the one or more second data link lines, the one or more third data link lines, and the one or more fourth data link lines disposed at respective layers may not overlap one another. For example, the one or more second data link lines disposed at the second layer B can be disposed among groups each including one or more of the first data link lines disposed at the first layer A. For example, the one or more third data link lines disposed at the third layer C can be disposed among groups each including one or more of the first data link lines disposed at the first layer A. For example, the one or more third data link lines disposed at the third layer C can be disposed among groups each including one or more of the second data link lines disposed at the second layer B. For example, the one or more fourth data link lines disposed at the fourth layer D can be disposed among groups each including one or more of the third data link lines disposed at the third layer C. For example, the one or more fourth data link lines disposed at the fourth layer D can be disposed among groups each including one or more of the first data link lines disposed at the first layer A. For example, the one or more fourth data link lines disposed at the fourth layer D can be disposed among groups each including one or more of the second data link lines disposed at the second layer B. In addition, the first to fourth data link lines disposed at respective layers can overlap with the data link lines adjacent thereto while having the same overlap area.

Each of the one or more first data link lines disposed at the first layer A, each of the one or more second data link lines disposed at the second layer B, each of the one or more third data link lines disposed at the third layer C, and each of the one or more fourth data link lines disposed at the fourth layer D can be electrically isolated or insulated from one another by insulating layers 11, 12, 13, and 14.

Although the embodiment in which each unit pixel is constituted by a red sub-pixel R, a green sub-pixel G, a blue sub-pixel B, and a green sub-pixel G has been described with reference to FIG. 11, one of the two green sub-pixels can be substituted by a white sub-pixel.

Accordingly, the data link lines can be configured to have the same overlay capacitance for different sub-pixels, without restriction of an overlay capacitance difference thereamong.

In accordance with the present disclosure, when data link lines are configured using four metal layers, and unit pixels each includes four sub-pixels, in accordance with an order of data lines of sub-pixels disposed on one horizontal pixel line, data lines of 4m−3th ones (m being a natural number) of the sub-pixels disposed on the one horizontal pixel line can be connected to a data driving IC by data link lines disposed at the first layer A, 4m−2th ones of the sub-pixels disposed on the one horizontal pixel line can be connected to the data driving IC by data link lines disposed at the second layer B, 4m−1th ones of the sub-pixels disposed on the one horizontal pixel line can be connected to the data driving IC by data link lines disposed at the third layer C, and 4mth ones of the sub-pixels disposed on the one horizontal pixel line can be connected to the data driving IC by data link lines disposed at the fourth layer D.

For example, the data lines of the 4m−3th sub-pixels disposed on the one horizontal pixel line can be connected to the data driving IC by the data link lines disposed at one of the four layers among the data link lines disposed at the four layers, the data lines of the 4m−2th sub-pixels disposed on the one horizontal pixel line can be connected to the data driving IC by the data link lines disposed at another one of the four layers among the data link lines disposed at the four layers, the data lines of the 4m−1th sub-pixels disposed on the one horizontal pixel line can be connected to the data driving IC by the data link lines disposed at another one of the four layers among the data link lines disposed at the four layers, and the data lines of the 4mth sub-pixels disposed on the one horizontal pixel line can be connected to the data driving IC by the data link lines disposed at the remaining one of the four layers among the data link lines disposed at the four layers.

A display apparatus according to various embodiments of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic diary, an electronic book, a portable multimedia player (PMP), a personal digital assistant (PDA), an MP3 player, a mobile medical appliance, a desktop computer, a laptop computer, a netbook computer, a workstation, a navigator, a vehicle navigator, a vehicle display apparatus, vehicle equipment, theater equipment, a theater display apparatus, a television, a wall paper appliance, a signage device, a gaming device, a notebook computer, a monitor, a camera, a camcorder, a home appliance, etc.

Display apparatuses according to various embodiments of the present disclosure can be explained as follows.

A display apparatus according to various embodiments of the present disclosure can include a display panel including an active area and a non-active area, a plurality of gate lines, a plurality of data lines, and a plurality of unit pixels being disposed in the active area, a data driving circuit connected to the plurality of data lines, and one or more data link lines disposed in the non-active area and configured to electrically connect the plurality of data lines to the data driving circuit, the one or more data link lines including at least two layers.

In accordance with various embodiments of the present disclosure, the one or more data link lines can be constituted by two layers, and each of the unit pixels can be constituted by three sub-pixels. Data lines of odd sub-pixels disposed on one horizontal pixel line can be connected to the data driving circuit by the data link lines disposed at one of the two layers among the data link lines disposed at the two layers. Data lines of even sub-pixels disposed on the one horizontal pixel line can be connected to the data driving circuit by the data link lines disposed at a remaining one of the two layers among the data link lines disposed at the two layers.

In accordance with various embodiments of the present disclosure, the one or more data link lines can be constituted by two layers, and each of the unit pixels can be constituted by four sub-pixels. Data lines of odd sub-pixels disposed on one horizontal pixel line can be connected to the data driving circuit by the data link lines disposed at one of the two layers among the data link lines disposed at the two layers. Data lines of even sub-pixels disposed on the one horizontal pixel line can be connected to the data driving circuit by the data link lines disposed at a remaining one of the two layers among the data link lines disposed at the two layers.

In accordance with various embodiments of the present disclosure, one or more first data link lines can be disposed at a first one of the two layers, and one or more second data link lines can be disposed at a second one of the two layers among groups each including one or more of the first data link lines.

In accordance with various embodiments of the present disclosure, the one or more second data link lines disposed at the second layer may not overlap with the one or more first data link lines disposed at the first layer.

In accordance with various embodiments of the present disclosure, the one or more second data link lines disposed at the second layer can overlap with the one or more first data link lines disposed at the first layer while having the same overlap area.

In accordance with various embodiments of the present disclosure, the one or more data link lines can be constituted by three layers, and each of the unit pixels can be constituted by three sub-pixels such that the unit pixels includes three kinds of sub-pixels. First ones of the three kinds of sub-pixels can be connected to the data driving circuit by the data link lines disposed at one of the three layers among the data link lines disposed at the three layers. Second ones of the three kinds of sub-pixels can be connected to the data driving circuit by the data link lines disposed at another one of the three layers among the data link lines disposed at the three layers. Third ones of the three kinds of sub-pixels can be connected to the data driving circuit by the data link lines disposed at a remaining one of the three layers among the data link lines disposed at the three layers.

In accordance with various embodiments of the present disclosure, one or more first data link lines can be disposed at a first one of the three layers. One or more second data link lines can be disposed at a second one of the three layers among groups each including one or more of the first data link lines. One or more third data link lines can be disposed at a third one of the three layers among groups each including adjacent ones of the first data link lines and the second data link lines.

In accordance with various embodiments of the present disclosure, the one or more data link lines can be constituted by three layers, and each of the unit pixels can be constituted by four sub-pixels such that the unit pixels include four kinds of sub-pixels. First ones of the four kinds of sub-pixels can be connected to the data driving circuit by the data link lines disposed at one of the three layers among the data link lines disposed at the three layers. Third ones of the four kinds of sub-pixels can be connected to the data driving circuit by the data link lines disposed at another one of the three layers among the data link lines disposed at the three layers. Second and fourth ones of the four kinds of sub-pixels can be connected to the data driving circuit by the data link lines disposed at a remaining one of the three layers among the data link lines disposed at the three layers.

In accordance with various embodiments of the present disclosure, one or more first data link lines can be disposed at a first one of the three layers. One or more second data link lines can be disposed at a second one of the three layers among groups each including one or more of the first data link lines. One or more third data link lines can be disposed at a third one of the three layers among groups each including adjacent ones of the first data link lines and the second data link lines.

In accordance with various embodiments of the present disclosure, the first to third data link lines may not overlap one another.

In accordance with various embodiments of the present disclosure, adjacent ones of the first to third data link lines overlap each other while having the same overlap area.

In accordance with various embodiments of the present disclosure, the one or more data link lines can be constituted by four layers, and each of the unit pixels can be constituted by three sub-pixels. The one or more data link lines can be connected to the data driving circuit by data link lines disposed at metal layers of an ascending or descending order, respectively, in accordance with an order of sub-pixels disposed on one horizontal pixel line.

In accordance with various embodiments of the present disclosure, data lines of first, seventh, and thirteenth ones of the sub-pixels disposed on the one horizontal pixel line can be connected to the data driving circuit by the data link lines disposed at a first one of the four layers. Data lines of second, sixth, eighth, twelfth, and fourteenth ones of the sub-pixels disposed on the one horizontal pixel line can be connected to the data driving circuit by the data link lines disposed at a second one of the four layers. Data lines of third, fifth, ninth, eleventh, and fifteenth ones of the sub-pixels disposed on the one horizontal pixel line can be connected to the data driving circuit by the data link lines disposed at a third one of the four layers. Data lines of fourth, tenth, and sixteenth ones of the sub-pixels disposed on the one horizontal pixel line can be connected to the data driving circuit by the data link lines disposed at a fourth one of the four layers.

In accordance with various embodiments of the present disclosure, one or more first data link lines can be disposed at a first one of the four layers. Two second data link lines can be disposed at a second one of the four layers between adjacent ones of the first data link lines. Two third data link lines can be disposed at a third one of the four layers between adjacent ones of the second data link lines. One fourth data link line can be disposed at a fourth one of the four layers between adjacent ones of the third data link lines.

In accordance with various embodiments of the present disclosure, the first to third data link lines may not overlap one another.

In accordance with various embodiments of the present disclosure, adjacent ones of the first to third data link lines overlap each other while having the same overlap area.

In accordance with various embodiments of the present disclosure, the one or more data link lines can be constituted by four layers, and each of the unit pixels can be constituted by four sub-pixels. Data lines of 4m−3th sub-pixels (m being a natural number) disposed on one horizontal pixel line can be connected to the data driving circuit by data link lines disposed at one of the four layers among data link lines disposed at the four layers. Data lines of 4m−2th sub-pixels disposed on the one horizontal pixel line can be connected to the data driving circuit by data link lines disposed at another one of the four layers among data link lines disposed at the four layers. Data lines of 4m−1th sub-pixels disposed on the one horizontal pixel line can be connected to the data driving circuit by data link lines disposed at another one of the four layers among data link lines disposed at the four layers. Data lines of 4mth sub-pixels disposed on the one horizontal pixel line can be connected to the data driving circuit by data link lines disposed at a remaining one of the four layers among data link lines disposed at the four layers.

In accordance with various embodiments of the present disclosure, one or more first data link lines can be disposed at a first one of the four layers. One second data link line can be disposed at a second one of the four layers between adjacent ones of the first data link lines. One third data link line can be disposed at a third one of the four layers between adjacent ones of the second data link lines. One or more fourth data link lines can be disposed at a fourth one of the four layers among groups each including adjacent ones of the third data link lines and the first data link lines.

In accordance with various embodiments of the present disclosure, the first to fourth data link lines may not overlap one another.

In accordance with various embodiments of the present disclosure, adjacent ones of the first to fourth data link lines can overlap each other while having the same overlap area.

In accordance with various embodiments of the present disclosure, each sub-pixel of each of the unit pixels can include a first thin film transistor disposed on a substrate, an auxiliary layer disposed on the substrate, a second thin film transistor disposed on the auxiliary layer, a light emitting element disposed on the second thin film transistor, and an intermediate electrode configured to interconnect the first thin film transistor and the light emitting element. The one or more data link lines of the at least two layers can be constituted by at least two metal layers among a metal layer identical to a first gate electrode of the first thin film transistor, a metal layer identical to the auxiliary layer, a metal layer identical to a second gate electrode of the second thin film transistor, a metal layer identical to a source electrode and a drain electrode of the first thin film transistor or the second thin film transistor, and a metal layer identical to the intermediate electrode.

In accordance with various embodiments of the present disclosure, one of the first and second thin film transistors can include one of an oxide semiconductor layer or a low-temperature polysilicon semiconductor layer.

In accordance with various embodiments of the present disclosure, the display apparatus can further include an encapsulation member disposed on the light emitting element, and a touch part disposed on the encapsulation member.

In accordance with the present disclosure, it can be possible to enhance accuracy of data voltages output to pixels from data link lines associated with the same color through equalization of parasitic capacitances among the data link lines.

In accordance with the present disclosure, it can be possible to enhance brightness compensation consistency and display quality of pixels through enhancement in accuracy of data voltages output to pixels from data link lines associated with the same color.

In accordance with the present disclosure, since brightness compensation consistency and display quality of pixels can be enhanced through equalization of parasitic capacitances among the data link lines, production energy for production of the display apparatus can be reduced, and greenhouse gases possibly generated due to a manufacturing process can be reduced. As such, environmental/social/governance (ESG) goals can be achieved.

Effects according to the embodiments of the present disclosure are not limited to the above-illustrated contents, and more various effects can be included in the present disclosure.

The present disclosure described above is not limited to the above-described embodiments and the accompanying drawings. Accordingly, it will be understood by those skilled in the art that various substitutions, changes, and modifications can be made without departing from the scope of the disclosure.

What is claimed is:

1. A display apparatus comprising:
a display panel comprising an active area and a non-active area, gate lines, data lines, and unit pixels being disposed in the active area;
a data driving circuit connected to the data lines; and
one or more data link lines disposed in the non-active area and configured to electrically connect the data lines to the data driving circuit, the one or more data link lines comprising at least two layers.

2. The display apparatus according to claim 1, wherein:
the one or more data link lines are constituted by two layers, and each of the unit pixels is constituted by three sub-pixels;
data lines of odd sub-pixels disposed on one horizontal pixel line are connected to the data driving circuit by the data link lines disposed at one of the two layers among the data link lines disposed at the two layers; and
data lines of even sub-pixels disposed on the one horizontal pixel line are connected to the data driving circuit by the data link lines disposed at a remaining one of the two layers among the data link lines disposed at the two layers.

3. The display apparatus according to claim 1, wherein:
the one or more data link lines are constituted by two layers, and each of the unit pixels is constituted by four sub-pixels;
data lines of odd sub-pixels disposed on one horizontal pixel line are connected to the data driving circuit by the data link lines disposed at one of the two layers among the data link lines disposed at the two layers; and
data lines of even sub-pixels disposed on the one horizontal pixel line are connected to the data driving circuit by the data link lines disposed at a remaining one of the two layers among the data link lines disposed at the two layers.

4. The display apparatus according to claim 2, wherein:
one or more first data link lines are disposed at a first one of the two layers; and
one or more second data link lines are disposed at a second one of the two layers among groups each comprising one or more of the first data link lines.

5. The display apparatus according to claim 4, wherein the one or more second data link lines disposed at the second layer do not overlap with the one or more first data link lines disposed at the first layer.

6. The display apparatus according to claim 4, wherein the one or more second data link lines disposed at the second layer overlap with the one or more first data link lines disposed at the first layer while having a same overlap area.

7. The display apparatus according to claim 1, wherein:
the one or more data link lines are constituted by three layers, and each of the unit pixels is constituted by three sub-pixels so that the unit pixels comprise three kinds of sub-pixels;
first ones of the three kinds of sub-pixels are connected to the data driving circuit by the data link lines disposed at one of the three layers among the data link lines disposed at the three layers;
second ones of the three kinds of sub-pixels are connected to the data driving circuit by the data link lines disposed at another one of the three layers among the data link lines disposed at the three layers; and
third ones of the three kinds of sub-pixels are connected to the data driving circuit by the data link lines disposed at a remaining one of the three layers among the data link lines disposed at the three layers.

8. The display apparatus according to claim 7, wherein:
one or more first data link lines are disposed at a first one of the three layers;
one or more second data link lines are disposed at a second one of the three layers among groups each comprising one or more of the first data link lines; and
one or more third data link lines are disposed at a third one of the three layers among groups each comprising adjacent ones of the first data link lines and the second data link lines.

9. The display apparatus according to claim 8, wherein the first to third data link lines do not overlap one another.

10. The display apparatus according to claim 8, wherein adjacent ones of the first to third data link lines overlap each other while having a same overlap area.

11. The display apparatus according to claim 1, wherein:
the one or more data link lines are constituted by three layers, and each of the unit pixels is constituted by four sub-pixels so that the unit pixels comprise four kinds of sub-pixels;
first ones of the four kinds of sub-pixels are connected to the data driving circuit by the data link lines disposed at one of the three layers among the data link lines disposed at the three layers;
third ones of the four kinds of sub-pixels are connected to the data driving circuit by the data link lines disposed at another one of the three layers among the data link lines disposed at the three layers; and
second and fourth ones of the four kinds of sub-pixels are connected to the data driving circuit by the data link lines disposed at a remaining one of the three layers among the data link lines disposed at the three layers.

12. The display apparatus according to claim 11, wherein:
one or more first data link lines are disposed at a first one of the three layers;
one or more second data link lines are disposed at a second one of the three layers among groups each comprising one or more of the first data link lines; and
one or more third data link lines are disposed at a third one of the three layers among groups each comprising adjacent ones of the first data link lines and the second data link lines.

13. The display apparatus according to claim 11, wherein the first to third data link lines do not overlap one another.

14. The display apparatus according to claim 11, wherein adjacent ones of the first to third data link lines overlap each other while having a same overlap area.

15. The display apparatus according to claim 1, wherein:
the one or more data link lines are constituted by four layers, and each of the unit pixels is constituted by three sub-pixels; and
the one or more data link lines are connected to the data driving circuit by data link lines disposed at metal layers of an ascending or descending order, respectively, in accordance with an order of sub-pixels disposed on one horizontal pixel line.

16. The display apparatus according to claim 15, wherein:
data lines of first, seventh, and thirteenth ones of the sub-pixels disposed on the one horizontal pixel line are connected to the data driving circuit by the data link lines disposed at a first one of the four layers;
data lines of second, sixth, eighth, twelfth, and fourteenth ones of the sub-pixels disposed on the one horizontal pixel line are connected to the data driving circuit by the data link lines disposed at a second one of the four layers;
data lines of third, fifth, ninth, eleventh, and fifteenth ones of the sub-pixels disposed on the one horizontal pixel line are connected to the data driving circuit by the data link lines disposed at a third one of the four layers; and
data lines of fourth, tenth, and sixteenth ones of the sub-pixels disposed on the one horizontal pixel line are connected to the data driving circuit by the data link lines disposed at a fourth one of the four layers.

17. The display apparatus according to claim 15, wherein:
one or more first data link lines are disposed at a first one of the four layers;
two second data link lines are disposed at a second one of the four layers between adjacent ones of the first data link lines;
two third data link lines are disposed at a third one of the four layers between adjacent ones of the second data link lines; and
one fourth data link line is disposed at a fourth one of the four layers between adjacent ones of the third data link lines.

18. The display apparatus according to claim 15, wherein the first to fourth data link lines do not overlap one another.

19. The display apparatus according to claim 15, wherein adjacent ones of the first to fourth data link lines overlap each other while having a same overlap area.

20. The display apparatus according to claim 1, wherein:
the one or more data link lines are constituted by four layers, and each of the unit pixels is constituted by four sub-pixels;
data lines of 4m−3th sub-pixels disposed on one horizontal pixel line are connected to the data driving circuit by data link lines disposed at one of the four layers among data link lines disposed at the four layers, where m is a natural number;
data lines of 4m−2th sub-pixels disposed on the one horizontal pixel line are connected to the data driving circuit by data link lines disposed at another one of the four layers among data link lines disposed at the four layers;
data lines of 4m−1th sub-pixels disposed on the one horizontal pixel line are connected to the data driving circuit by data link lines disposed at another one of the four layers among data link lines disposed at the four layers; and
data lines of 4mth sub-pixels disposed on the one horizontal pixel line are connected to the data driving circuit by data link lines disposed at a remaining one of the four layers among data link lines disposed at the four layers.

21. The display apparatus according to claim 20, wherein:
one or more first data link lines are disposed at a first one of the four layers;
one second data link line is disposed at a second one of the four layers between adjacent ones of the first data link lines;
one third data link line is disposed at a third one of the four layers between adjacent ones of the second data link lines; and
one or more fourth data link lines are disposed at a fourth one of the four layers among groups each comprising adjacent ones of the third data link lines and the first data link lines.

22. The display apparatus according to claim 21, wherein the first to fourth data link lines do not overlap one another.

23. The display apparatus according to claim 21, wherein adjacent ones of the first to fourth data link lines overlap each other while having a same overlap area.

24. The display apparatus according to claim 1, wherein:
each sub-pixel of each of the unit pixels comprises:
a first thin film transistor disposed on a substrate,
an auxiliary layer disposed on the substrate,
a second thin film transistor disposed on the auxiliary layer,
a light emitting element disposed on the second thin film transistor, and
an intermediate electrode configured to interconnect the first thin film transistor and the light emitting element; and
the one or more data link lines of the at least two layers are constituted by at least two metal layers among:
a metal layer identical to a first gate electrode of the first thin film transistor,
a metal layer identical to the auxiliary layer,
a metal layer identical to a second gate electrode of the second thin film transistor,
a metal layer identical to a source electrode and a drain electrode of the first thin film transistor or the second thin film transistor, and
a metal layer identical to the intermediate electrode.

25. The display apparatus according to claim 24, wherein one of the first and second thin film transistors comprises one of an oxide semiconductor layer or a low-temperature polysilicon semiconductor layer.

26. The display apparatus according to claim 24, further comprising:
an encapsulation member disposed on the light emitting element; and
a touch part disposed on the encapsulation member.
